(19) United States
(12) Patent Application Publication
(10) Pub. No.: US 2022/0149865 A1
(43) Pub. Date: May 12, 2022

(54) PERMUTATION-BASED CODING FOR DATA STORAGE AND DATA TRANSMISSION

(71) Applicant: USE-256 B.V., Hengelo (NL)

(72) Inventor: Johannes Gerardus DE FROE, Hengelo (NL)

(73) Assignee: USE-256 B.V., Hengelo (NL)

(21) Appl. No.: 17/626,195

(22) PCT Filed: Jul. 15, 2020
(86) PCT No.: PCT/EP2020/070003

§ 371 Date: Jan. 11, 2022

(30) Foreign Application Priority Data
Jul. 15, 2019 (EP) 19186347.1

(51) Int. Cl. H03M 7/30

(52) U.S. Cl. CPC H03M 7/3077; H03M 7/6005; H03M 7/6011

(57) ABSTRACT

Methods of encoding and decoding data are described wherein the encoding method comprises: receiving a data file and dividing the data file or data stream into one or more data blocks, each data block having a predetermined size N and comprising a sequence of data units, e.g. byte values; and, iteratively encoding the data file into a data key based on a first permutation function and a first dictionary of permutation indices, preferably the encoded data file having a total size that is equal to or smaller than the original data file and preferably the data key having a size that is equal to or smaller than size of a data block. Iteratively encoding the data file comprises one or more encoding iterations, wherein each encoding iteration includes: determining a first permutation index defining a permutation to generate the first input data block from a first ordered data block, the generating including providing at least the first input data block to an input of the first permutation function, and the first ordered data block being obtainable by ordering the first input data block; determining a first permutation dictionary index representing a location in the first dictionary in which the first permutation index is stored; generating a first frequency data block defining the number of occurrences for each potential data value in the input data block, preferably determining the number of occurrences for each potential data value in the input data block and ordering the determined occurrences in a sequence of values in a hierarchical order, e.g. increasing or decreasing order of the data value; processing the frequency data block; and determining an encoded data block, the encoded data block comprising the first permutation dictionary index and the processed frequency data block. The encoding method further comprises outputting the data key comprising the one or more encoded data blocks and, optionally, iteration information.

### FIELD OF THE INVENTION

The invention relates to permutation-based coding for data storage and data transmission, and in particular, though not exclusively, to methods and systems for permutation-based coding for data storage and data transmission and to a computer-program product using such methods.

### BACKGROUND OF THE INVENTION

Currently the amount of data used in everyday processes and services is growing exponentially. These developments have made data coding algorithms indispensable for handling, e.g. storing, processing and transmitting large amounts of data. Two important classes of coding algorithms are data compression algorithms and data encryption algorithms. Data compression algorithms are configured to remove redundancy in data files so that data can be stored more efficiently and transmitted with reduced bandwidth. In many cases, data compression needs to be lossless, i.e. no information is lost during compression. Data encryption algorithms are configured to secure access to the data in order to prevent unauthorized access to the data.

Typically, when both secure and efficient data storage and transmission is needed, a data compression algorithm is used in combination with an encryption technique. Such combined use of algorithm makes the data processing computation intensive. The effect of encryption operations may have a conflicting effect on compression operations. Moreover, the more elevated the level of compression and the level of security that is required, the more complex the algorithms which will even increase the computation burden further, thereby inhibiting commercial applications. For commercial applications, a coding algorithm needs to be fast, flexible to handle different types of data and data should have predictable lengths (format) so that they can be handled by storage or transmission systems. These requirements will often lead to a compromise in terms of compression and security level.

Some of the aforementioned problems may be solved by introducing new technologies, like cloud computing and optical fiber, which allow ever increasing data storage and data transmission. However, implementation of such technologies is typically limited to well-developed geographical areas that have a suitable infrastructure, while access to such high-performance technologies in more remote areas is often not available. Moreover, even if a suitable infrastructure is available, often general encryption schemes like AES cannot be used in certain important applications like video because these encryption schemes interfere with the requirements for high-quality video transmission such as speed and high data compression. For that reason, digital right management (DRM) schemes are used for secure distribution of video.

The Burrows-Wheeler Transform is a block-sorting coding scheme in which data in a block are rearranged based on permutations so that the coded data can be efficiently compressed using a conventional compression scheme, e.g. run-length encoding. BWT is primarily a pre-processing step for increasing the compression of a data block by a conventional compression scheme. Permutation techniques are also used in U.S. Pat. No. 8,189,664, which describes a lossless permutation-based encryption/compression method for video data. Similar permutation-based coding schemes for video coding are described by A. Mihnea, “Permutation-based data compression”, PhD thesis, December 2011. These algorithms are specially adapted to video coding and cannot be readily applied to more generic coding applications in which a coding scheme should be able to handle any type of data file or data stream.

Hence, from the above it follows that there is a need in the art for generic coding tools that allow storage and transmission of large amounts of information in an efficient and secure way. In particular, there is a need in the art for generic coding algorithms that allow different types of data to be coded into a data format for efficient and secure data storage and data transmission for a large variety of applications.

### SUMMARY OF THE INVENTION

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Functions described in this disclosure may be implemented as an algorithm executed by a microprocessor of a computer. Furthermore, aspects of the present invention may take the form of a computer program product embodied in one or more computer readable medium(s) having computer readable program code embodied, e.g., stored, thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber, cable, RF, etc., or any suitable combination of the foregoing. Computer program code for carrying out operations for aspects of the present invention may be written in any combination of one or more programming languages, including an object-oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor, in particular a microprocessor or central processing unit (CPU), of a general purpose computer, special purpose computer, or other programmable data processing apparatus to produce a machine, such that the instructions, which execute via the processor of the computer, other programmable data processing apparatus, or other devices create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks. Additionally, the Instructions may be executed by any type of processors, including but not limited to one or more digital signal processors (DSPs), general purpose microprocessors, application specific integrated circuits (ASICs), field programmable logic arrays (FP-GAs), or other equivalent integrated or discrete logic circuitry.

The flowchart and block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

In an aspect, the invention may relate to a method of encoding data by an encoding apparatus, the method comprising: receiving a data file or data stream and dividing the data file or data stream into one or more input data blocks, each input data block having a predetermined size N and comprising a sequence of data units, e.g. byte values, preferably the data units having N or less distinct potential values; and, iteratively encoding the data file into a data key based on a first permutation function and a first dictionary of permutation indices, preferably the encoded data file having a total size that is equal to or smaller than the original data file and preferably the data key having a size that is equal to or smaller than size of an input data block.

In an embodiment, iteratively encoding the data file may comprise one or more encoding iterations, wherein each encoding iteration may include: determining a first permutation index defining a permutation to generate the first input data block from a first ordered data block, the generating including providing at least the first input data block to an input of the first permutation function, and the first ordered data block being obtainable by ordering the first input data block; determining a first permutation dictionary index representing a location in the first dictionary in which the first permutation index is stored; generating a frequency data block defining the number of occurrences for each potential data value in the input data block, preferably determining the number of occurrences for each potential data value in the input data block and ordering the determined occurrences in a sequence of values in a hierarchical order, e.g. increasing or decreasing order of the data value; processing, preferably compressing, the frequency data block; and determining an encoded data block, the encoded data block comprising the first permutation dictionary index and the processed frequency data block. The method may further comprise outputting the data key comprising the one or more encoded data blocks and, optionally, iteration information.

The lossless coding schemes described in the embodiments of this application may have both a compression aspect and an encryption aspect. The lossless coding schemes described in the embodiments of this application allow encoding of any file type (.exe, .bin, .mp3, .mpeg, .wav, etc.) into a data key of a predetermined size, e.g. N bytes, using a permutation function that transforms an input data block (which may be regarded as a permutation of an ordered data block, i.e. an ordered sequence of symbols or values) into a permutation index defining a permutation that reorders the input data block into the ordered data block or vice versa. In some embodiments, the ordered data block need not be constructed explicitly. The ordered data block has a high redundancy. This may be exploited by determining frequency data for all potential values of the data units in the input data block, possibly after a suitable conversion of the input data (e.g. 8-bit bytes into 4-bit nibbles). As a single dictionary may be used to encode a plurality of data files, the compression aspect of the encoding may be more efficient when large amounts of data are being encoded, e.g. a library of video files, as in that case, dictionary entries may be reused.

It should be noted that the encoding scheme results in a (relatively large) permutation dictionary storing permutation indices, and a (relatively small) data key. Both the dictionary and the data key are required to reconstruct the original data. Therefore, the coding scheme may be considered an encryption scheme, wherein e.g. the data key may be kept secret and may be used to ‘unlock’ the dictionary. The dictionary, however, only comprises information about how ordered data blocks must be shuffled (permuted) to decode the data, but it does not comprise the data to be permuted. In this regard, the disclosed encoding scheme differs from classical encryption schemes, in which all input data is present in the encrypted data file, while the decryption key may be independent of the encrypted data.

In an embodiment, during encoding, the algorithm may build a dictionary of permutation indices. In another embodiment, the algorithm may use an already existing dictionary of permutation indices. A decoding algorithm may use the same dictionary that was used during encoding or a dictionary that at least comprises the permutation indices that were also contained in the dictionary that was used by the encoder to encode the data file. Further, it may use a permutation function that allows a permutation index of an ordered data block to be transformed into a permutation, so that the original data block can be recovered without any loss.

During encoding, a library of permutation indices will be built. The more data is encoded, the slower the library will grow and after encoding a large enough amount of data, the size of the dictionary will no longer grow. Such fully grown dictionary may be used by encoding and decoding devices to encode and securely distribute large data files based on a small data key.

The coding algorithm that is used in the embodiments of this application is not a conventional compression or encryption algorithm. On the contrary, it combines the advantages of both compression and encryption, providing both secure and efficient storage and distribution of data file. The coding algorithm offers a unique method of storing and restoring data. While the amount of data to transport is kept to a minimum, large amounts of data can be relayed using a very small footprint, with no loss of data. At both ends of the transmission, the sender and the receiver will need to have the same dictionary.

The main idea behind the coding algorithm is to store commonly used data patterns in data files only once in the form of permutations. The algorithm treats each data file as sequence of values or symbols irrespective of its type. By treating a data block as a sequence values or symbols, it is possible to encode a data block in to an encoded data block that has a smaller size than the data block. This also opens the possibility to divide a data file into data blocks of equal size, to encode the data blocks into encoded data blocks and to use the encoded data blocks as a data file for a next encoding iteration (i.e. divide the data file into blocks and encode each block). This way, the data file can be iteratively encoded into a data key of a predetermined size, e.g. the size of a data block or smaller.

A further benefit of the coding schemes described in this application is that the dictionary and the data key represent the original data in a fully scrambled way which cannot be recovered without the dictionary, a data key and the coding algorithms. That means that the original data file cannot be restored on the basis of the dictionary without the corresponding data key and the decoding algorithm.

In an embodiment, processing the frequency data block may include generating a second ordered data block based on the frequency data block, and determining a second permutation index defining a permutation to generate the frequency data block from the second ordered data block, the generating including providing at least the frequency data block to an input of the first permutation function. Optionally, processing the frequency data block may also include determining a second permutation dictionary index representing a location in the first dictionary in which the second permutation index is stored. Processing the frequency data block may further include determining a processed frequency data block, the processed frequency data block comprising a representation of the second ordered data block, and the second permutation index or the second permutation dictionary index.

This way, the frequency data block may be compressed using essentially the same steps that were used to generate the frequency data block and the first permutation, allowing for efficient software coding. The second ordered data block may be represented using a dense format, comprising e.g. only the non-zero entries.

In an embodiment, the generating a second ordered data block may include: determining a frequency, e.g. the number of occurrences, for each data value in the frequency data block. Generating a second ordered data block may further include ordering the determined frequencies in a sequence of values in a hierarchical order, e.g. increasing or decreasing order; or determining a list of non-zero elements and corresponding frequencies. Thus, the second ordered data block preferably may comprise a list of non-zero elements and corresponding frequencies. Because the frequency data block typically comprises few non-zero elements, the second ordered data block may be reduced in size compared to the frequency data block.

In an embodiment, determining a first permutation index may further comprise generating a first ordered data block based on the first input data block and providing the first ordered data block to an input of the first permutation function.

In an embodiment, before generating the first ordered data block, the method may further comprise converting the data units in the first data block into ascii code, preferably converting data units, for example byte values, of the first data block into ascii codes. Alternatively or additionally, the method may further comprise, before generating the first frequency data block, dividing the data units the first input data block into smaller data units, preferably dividing byte values into nibble values.

Thus, before sorting and ordering the first data block, byte values may be converted to ascii code. For example, the number 255 may be may be represented by 0xFF in hexadecimal notation. This hexadecimal number may be subsequently transformed into two ascii codes 70 70, i.e. the ascii code for the symbol F in decimal notation. Although such transformation would lead to block sizes that are twice the size of the original bock size, it nevertheless may lead to a substantial improvement in coding efficiency (a factor of 10 or more). This is because a byte value may represent 256 different numbers (e.g. 0-255), whereas the ascii code only 16 (namely the ascii codes for 0-9 and a-f) so that the permutation indices and the ordering process can be determined much faster. Alternatively, a similar result may be obtained by dividing bytes into nibbles, 8-bit bytes potentially representing 256 different values and 4-bit nibbles potentially representing 16 different values.

In an embodiment, determining a first permutation dictionary index may include: determining if the first permutation index is already stored in the first dictionary; if the first permutation index is not stored in the dictionary, storing the first permutation index in the first dictionary and receiving the first permutation dictionary index associated with the first permutation index; or, if the first permutation index is stored in the first dictionary, receiving the first permutation dictionary index associated with the first permutation index.

In an embodiment, iteratively encoding the data file may comprise: generating iteration information, the iteration information providing information about the number of encoding iterations needed for encoding the data file.

In an embodiment, the process of iteratively encoding the data file into an encoded data file may be stopped if the size of the encoded data file is equal to or smaller than a predetermined size, preferably the size of a data block.

In an embodiment, the data file may be a multimedia file, such as a video file; and/or, wherein the data stream is a multimedia stream, such as a video stream.

In an embodiment, iteratively encoding the data file may comprise one or more encoding iterations, wherein each encoding iteration may include: generating a first ordered data block based on a first data block of the one or more data blocks; determining a first permutation index based on the first data block and the first ordered data block, the generating including providing the first data block and the first ordered data block to an input of the first permutation function; determining a dictionary index representing a location in the first dictionary in which the first permutation index is stored; generating a second ordered data block based on a second data block, the second data block representing symbols or values of the first ordered data block; determining a second permutation index based on the second block and the second ordered block, the determining including providing the second block and the second ordered block to the input of the first permutation function; and, determining an encoded data block comprising the dictionary index, the second ordered data block and the second permutation index.

In an embodiment, the generating a first ordered data block may include: determining a frequency, e.g. the number of occurrences, for each data value in the input data block; and, ordering the determined frequencies in a sequence of values in a hierarchical order, e.g. increasing or decreasing order.

In an aspect, the invention may relate to a method of decoding an encoded data file by a decoding apparatus, the encoded data file being encoded by an encoder apparatus into a data key based on a first dictionary of permutation indices and a first permutation function. The method may comprise receiving a data key, the data key comprising one or more encoded data blocks, and, optionally, iteration information, an encoded data block comprising a first permutation dictionary index, and a processed first frequency data block; and iteratively decoding the data key into a decoded data file based on a second permutation function, preferably an inverse of the first permutation function, and a second dictionary of permutation indices, the second dictionary comprising at least the permutation indices contained in the first dictionary associated with the encoded file.

In an embodiment, iteratively decoding the encoded data file may comprise one or more decoding iterations, each decoding iteration comprising: retrieving an encoded data block from the data key, the encoded data block comprising a first permutation dictionary index associated with a first permutation index and a processed first frequency data block; retrieving the first permutation index from the second dictionary using the first permutation dictionary index; generating a first frequency data block based on the processed first frequency data block; and determining an original data block based on the first frequency data block and the first permutation index, the determining including providing the first frequency data block or a first ordered data block based on the first frequency data block and the first permutation index to the input of the second permutation function. The method may further comprise combining the one or more original data blocks into a decoded file.

In an embodiment, the processed first frequency data block may comprise a second ordered data block and a second permutation index or a second permutation dictionary index. In such an embodiment, decoding the encoded data file may further comprise; optionally, retrieving the second permutation index from the second dictionary using the second permutation dictionary index; determining a second data block based on the second ordered data block and the second permutation index, the determining including providing the second ordered data block and the second permutation index to the input of the second permutation function; and generating a first frequency data block based on the second data block, e.g. using the second data block as the first frequency data block.

In an embodiment, iteratively decoding the encoded data file may comprise: receiving an encoded data block, the encoded data block comprising a dictionary index associated with first permutation index, a first ordered data block and a second permutation index; retrieving the first permutation index from a dictionary using the dictionary index; determining a first data block based on the first ordered data block and the second permutation index, the determining including providing the first ordered data block and the second permutation block to the input of the second permutation function; and, using the first data block as a second ordered data block, and determining an original data block based on the second ordered data block and the first permutation index, the determining including providing the second ordered data block and the first permutation block to the input of the second permutation function.

In an embodiment, the second dictionary may comprise the same permutation indices as the permutation indices of a first dictionary that was used by an encoder apparatus that was used to encode the data file into the data key.

In an embodiment, the invention may relate to a method of decoding an encoded data file by decoding apparatus, the encoded data file being encoded by an encoder apparatus into a data key based on a first dictionary of permutation indices and a first permutation function, wherein the method may comprise: receiving a data key, the data key comprising a dictionary index, an ordered data block and a permutation index, and, optionally, iteration information; and, iteratively decoding the data key into a decoded data file based a second permutation function and a dictionary of permutation indices.

In an aspect, the invention may relate to an encoding apparatus comprising a computer readable storage medium having at least part of a program embodied therewith; and, a computer readable storage medium having computer readable program code embodied therewith, and a processor, preferably a microprocessor, coupled to the computer readable storage medium, wherein responsive to executing the computer readable program code, the processor is configured to perform any of the encoding method steps described above. In particular, the processor may be configured to perform executable operations comprising receiving a data file and dividing the data file or data stream into one or more data blocks, each data block having a predetermined size N and comprising a sequence of data units, e.g. byte values; and, iteratively encoding the data file into a data key based on a first permutation function and a first dictionary of permutation indices, preferably the encoded data file having a total size that is equal to or smaller than the original data file and preferably the data key having a size that is equal to or smaller than size of a data block.

In an embodiment, iteratively encoding the data file may comprise one or more encoding iterations, wherein each encoding iteration may include: determining a first permutation index defining a permutation to generate the first input data block from a first ordered data block, the generating including providing at least the first input data block to an input of the first permutation function, and the first ordered data block being obtainable by ordering the first input data block; determining a first permutation dictionary index representing a location in the first dictionary in which the first permutation index is stored; generating a first frequency data block defining the number of occurrences for each potential data value in the input data block, preferably determining the number of occurrences for each potential data value in the input data block and ordering the determined occurrences in a sequence of values in a hierarchical order, e.g. increasing or decreasing order of the data value; processing the frequency data block; and determining an encoded data block, the encoded data block comprising the first permutation dictionary index and the processed frequency data block. The method may further comprise outputting the data key comprising the one or more encoded data blocks and, optionally, iteration information.

In an embodiment, processing the frequency data block may include generating a second ordered data block based on the frequency data block, and determining a second permutation index defining a permutation to generate the frequency data block from the second ordered data block, the generating including providing at least the frequency data block to an input of the first permutation function. Optionally, processing the frequency data block may also include determining a second permutation dictionary index representing a location in the first dictionary in which the second permutation index is stored. Processing the frequency data block may further include determining a processed frequency data block, the processed frequency data block comprising the second ordered data block, and the second permutation index or the second permutation dictionary index.

In an embodiment, generating a first ordered data block may include: determining a frequency, e.g. the number of occurrences, for each data value in the data block; and, ordering the determined frequencies in a sequence of values in a hierarchical order, e.g. increasing or decreasing order.

In an embodiment, before generating the first ordered data block, the executable operations may further comprise converting the data units in the first data block into ascii code, preferably converting data units, for example byte values, of the first data block into ascii codes; and/or dividing the data units in the first input data block into smaller data units, preferably dividing byte values into nibble values.

In an embodiment, determining a first permutation dictionary index may include: determining if the first permutation index is already stored in the first dictionary; if the first permutation index is not stored in the dictionary, storing the first permutation index in the first dictionary and receiving the first permutation dictionary index associated with the first permutation index; or, if the first permutation index is stored in the first dictionary, receiving the first permutation dictionary index associated with the first permutation index.

In an embodiment, iteratively encoding the data file may comprise generating iteration information, the iteration information providing information about the number of encoding iterations needed for encoding the data file.

In an embodiment, the process of iteratively encoding the data file into an encoded data file may be stopped if the size of the encoded data file is equal to or smaller than a predetermined size, preferably the size of a data block.

In a further aspect, the invention may relate to a decoding apparatus comprising: a computer readable storage medium having at least part of a program embodied therewith; and, a computer readable storage medium having computer readable program code embodied therewith, and a processor, preferably a microprocessor, coupled to the computer readable storage medium, wherein responsive to executing the computer readable program code, the processor is configured to perform any of the encoding method steps described above. In particular, the processor may be configured to perform executable operations comprising: receiving a data key, the data key comprising one or more encoded data blocks, and, optionally, iteration information, an encoded data block comprising a first permutation dictionary index, and a processed first frequency data block; and iteratively decoding the data key into a decoded data file based on a second permutation function, preferably an inverse of the first permutation function, and a second dictionary of permutation indices, the second dictionary comprising at least the permutation indices contained in the first dictionary associated with the encoded file.

In an embodiment, iteratively decoding the encoded data file may comprise one or more decoding iterations, each decoding iteration comprising: retrieving an encoded data block from the data key, the encoded data block comprising a first permutation dictionary index associated with a first permutation index and a processed first frequency data block; retrieving the first permutation index from the second dictionary using the first permutation dictionary index; generating a first frequency data block based on the processed first frequency data block; and determining an original data block based on the first frequency data block and the first permutation index, the determining including providing the first frequency data block or a first ordered data block based on the first frequency data block and the first permutation index to the input of the second permutation function. The method may further comprise combining the one or more original data blocks into a decoded file.

In an embodiment, the processed first frequency data block may comprise a second ordered data block and a second permutation index or a second permutation dictionary index. In such an embodiment, decoding the encoded data file may further comprise; optionally, retrieving the second permutation index from the second dictionary using the second permutation dictionary index; determining a second data block based on the second ordered data block and the second permutation index, the determining including providing the second ordered data block and the second permutation index to the input of the second permutation function; and generating a first frequency data block based on the second data block, e.g. using the second data block as the first frequency data block. In an embodiment, the second dictionary may comprise the same permutation indices as the permutation indices of a first dictionary that was used by an encoder apparatus that was used to encode the data file into the data key.

The invention may also relate to a computer program or suite of computer programs comprising at least one software code portion or a computer program product storing at least one software code portion, the software code portion, when run on a computer system, being configured for executing any of the method steps described above.

The invention may further relate to a non-transitory computer-readable storage medium storing at least one software code portion, the software code portion, when executed or processed by a computer, is configured to perform any of the method steps as described above.

The invention will be further illustrated with reference to the attached drawings, which schematically will show embodiments according to the invention. It will be understood that the invention is not in any way restricted to these specific embodiments.

### BRIEF DESCRIPTION OF THE DRAWINGS

FIG. 1 depicts a permutation table for an ordered sequence of symbols.

FIGS. 2A and 2B depict two permutation functions which are used in the embodiments in this application.

FIG. 3 depicts an encoding process according to an embodiment of the invention.

FIG. 4 depicts a first part of an encoding process according to an embodiment of the invention.

FIG. 5 depicts a second part of an encoding process according to an embodiment of the invention.

FIG. 6 depicts a third part of an encoding process according to an embodiment of the invention.

FIG. 7 depicts the result of the encoding process according to an embodiment of the invention.

FIGS. 8A and 8B depict two flow diagrams of encoding processes according to embodiments of the invention.

FIG. 9 depicts a flow diagram of a decoding process according to an embodiment of the invention.

FIG. 10 depicts a first part of a decoding process according to an embodiment of the invention.

FIG. 11 depicts a second part of a decoding process according to an embodiment of the invention.

FIGS. 12A and 12B depict two flow diagrams of decoding processes according to a embodiments of the invention.

FIGS. 13A and 13B depict graphs displaying the relation between original data size and dictionary size.

FIG. 14 depicts a schematic of a video encoding and decoding system that may use the techniques described in this application.

FIGS. 15A and 15B depict an exemplary application of the embodiments in this application.

### DETAILED DESCRIPTION

The aim of the embodiments described in this application are coding algorithms based on permutation functions for efficiently and securely storing and transmitting data. A permutation is a reordering of an ordered sequence of symbols or values, which plays an important role in algorithms. Different permutations of an ordered sequence may be indexed by a unique permutation index. This way, a sequence of data (values or symbols) may be regarded as a permutation which can be represented by an ordered sequence and a permutation index. It has been surprisingly found that permutation techniques can be used to code data blocks for efficient and secure data storage and transmission, despite the fact that the combination of the ordered sequence and the permutation index, as such, may result in a bigger (bit wise) value. For example, the number of permutations for two bytes is 2!=2, wherein each byte may represent a value between 0 to 255 resulting in 256*256=65536 combinations. The number of ordered sequences for two bytes is 32896. Hence, whereas the two bytes contain a total of 16 bits, the combination of the permutation index i (i=1,2) and the ordered sequence contain a total of 17 bits, i.e. more bits than the actual 16 bit of the original sequence. Below the permutation-based coding schemes and their advantages are described in more detail within references to the figures.

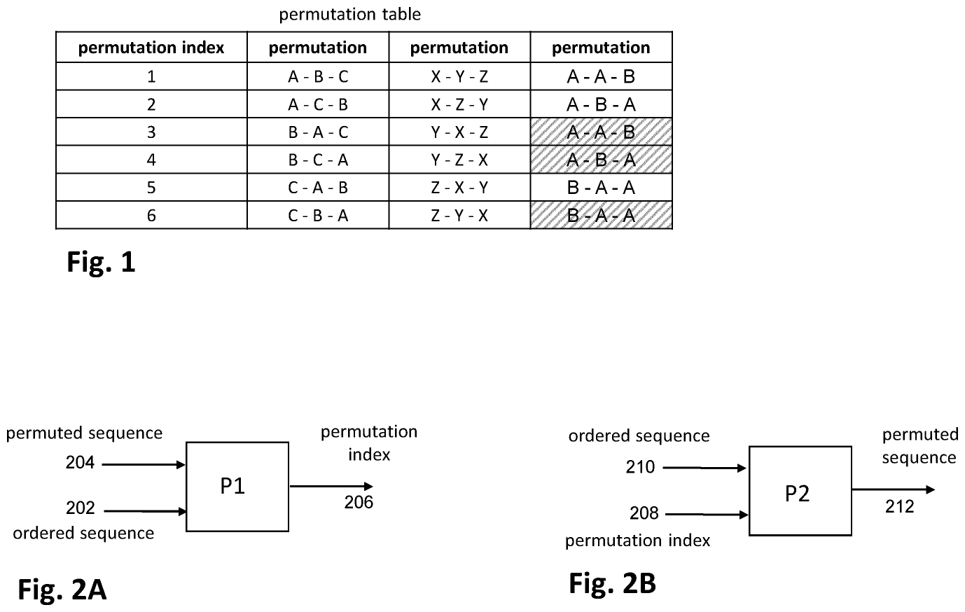

FIG. 1 depicts an example of a simple permutation table for an ordered sequence of data units, e.g. symbols such as letters or ascii characters, or values such as byte values or hexadecimal values. As shown in this figure, the sequence of letters C-B-A may define a permutation of the ordered sequence of letters A-B-C, wherein the permutation may have permutation index 6. Thus, based on the permutation table, a permutation index can be determined if an ordered sequence and a permutation is known. Similarly, a permutation can be determined if an ordered sequence and a permutation index is known. The permutation table illustrates the relation between an ordered set, a permutation of the ordered set and the permutation index of the permutation.

The second column shows that the same permutation indices may be used to define permutations of different data sets. A permutation index 6 combined with ordered data set A-B-C may result in a permutation C-B-A, while the same permutation index 6 combined with ordered data set X-Y-Z may result in permutation Z-Y-X. Clearly, both the permutation index and the ordered data set and the table or function mapping permutations to permutation indices must be known in order to reconstruct the original permutation. If any of these is unknown, it is impossible to reconstruct the original data.

The third column shows that if the data set comprises identical elements, the number of permutation indices required to describe all possible permutations is reduced. The hatched entries indicate duplicate permutations. For example, for ordered sequence A-A-B, permutation index 4 yields the same permutation as permutation index 2, namely A-B-A. In this example, only permutation indices 1, 2, and 5 are needed to define all unique permutations of the ordered sequence A-A-B. In such a case, the permutation indices may be renumbered.

Instead of using a table, the index or the permutation may be computed based on a permutation function. Such permutation function can be extended to permutations of an ordered sequence of N symbols, whereas the size of the table will grow rapidly with N. Various such functions are known in the art. This functional relation is depicted in FIGS. 2A and 2B. FIG. 2A depicts a first permutation function P1, which may receive a permutation 204 and an ordered sequence 202 at its input and returns a permutation index 206 at its output. In an embodiment, it may not be required to explicitly construct the ordered sequence. Instead the ordered sequence may be provided implicitly, e.g. by counting the frequency of each possible value and providing the frequency count of each possible value. In yet another embodiment, the first permutation function may only receive the permuted sequence as input. In such an embodiment, the first permutation function may output the ordered data set and the corresponding permutation index.

In an embodiment, the first permutation function may comprise a secret parameter and/or a hardware dependent parameter. For example, the computation of the permutation index may depend on a MAC address of the device, or a unique ID of a removable storage device. This may increase the security, as copying a database with permutation indices to a different device with a different parameter (e.g., UID) may lead to different permutations being generated.

An example of the first permutation algorithm in pseudo code is provided below wherein the attribute perm defines a permutation of an ordered sequence d of data units, e.g. symbols or values, the attribute n the length of the sequence of symbols or values and the attribute index represents the permutation index of the attribute permutation:

```
begin interface function perm2index(perm, n)
  dcl perm int[n]
  dcl n int
  return int
end interface
begin function perm2index
  dcl i, j int
  dcl d int[ ]
  dcl index int
  copy(src=perm, dest=d)
  begin loop i = 0, ..., n−2
    begin loop j = i+1, ..., n−1
      if (d[j] .gt. d[i]) d[j] −= 1
    end loop
  end loop
  begin loop i = 0, ... , n−2; init index = 0; init j = n−1
    index = j*(index + d[i])
    j −= 1
  end loop
  return index
end function
```

FIG. 2B depicts a second permutation function P2, which may receive a permutation index 208 and an ordered sequence 210 at its input and returns a permutation 212 at its output. Second permutation function P2 may be an inverse of first permutation function P1 in the sense that for each permutation sequence perm, P2(P1 (perm, d), d)=perm. That is, when provided with the ordered sequence and the permutation index computed by P1, P2 may compute the original permutation. An example of the permutation algorithm in pseudo code is provided below:

```
begin interface function index2perm(index, d, n)
  dcl index int
  dcl n int
  dcl d int[n]
  return int[n]
end interface
begin function index2perm
  dcl i, j int
  dcl perm int[n]
  d[n−1] = 0
  begin loop i = 2, ..., n−2; init j = n−2
    d[j] = modulo(index,i)
    index /= i
    j −= 1
  end loop
  copy(src=d, dest=perm)
  begin loop i = 0, ..., n−2
    begin loop j = i+1, ..., n−1
      if (perm[j] .ge. perm[i]) perm[j] += 1
    end loop
  end loop
  return perm
end function
```

As will be explained in more detail, these permutation functions may be used in a coding scheme that allows both secure and efficient storage and transmission of data.

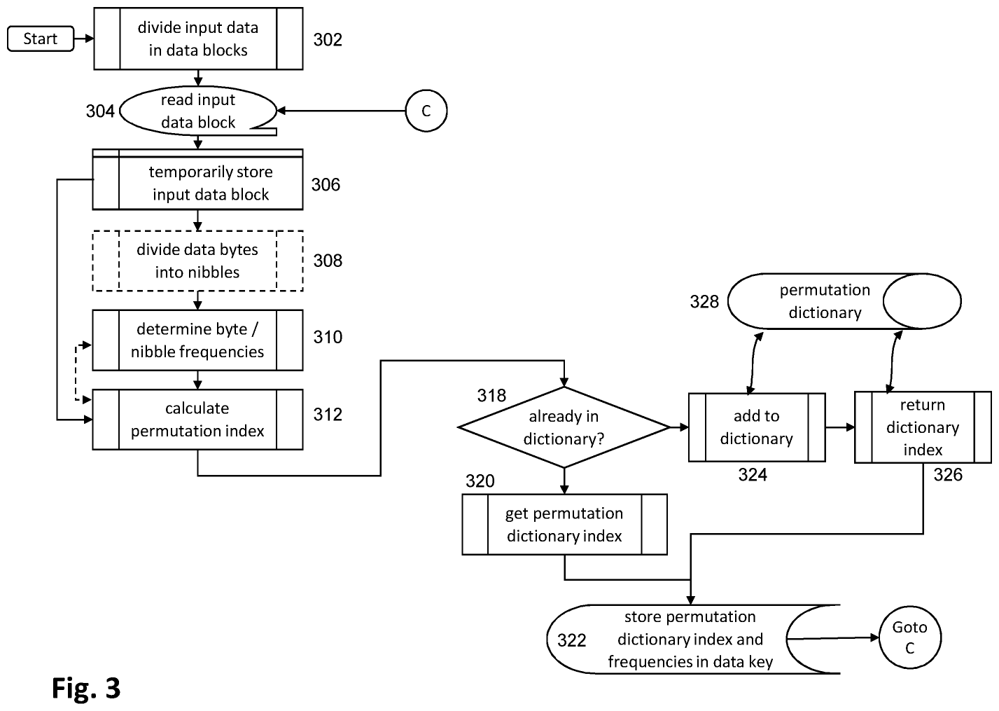

FIG. 3 depicts an encoding process according to an embodiment of the invention. FIG. 3 depicts an encoding process, wherein in a first step 302 a data file or data stream may be divided into input data blocks of a predetermined length N. Here, each block may be formatted as an array of N data units, wherein the data units may represent a symbol (letters, numbers, etc.) that can be ordered, e.g. ascii symbols representing numbers and letters, byte values representing a value between 0-255, etc. For example, the block may define an array of 128 bytes (N=128). Each byte value may represent a value between 0 and 255. If the length of the data block is not equal to a multiple of N, the remaining data units may be stored in a temporary buffer. The remaining bytes may be added to the final result when all blocks are processed. For example, a file of 12000 bytes may result into 93 blocks of 128 bytes to be processed, wherein the remaining 96 bytes may be temporary stored.

After dividing the data file or data stream into input data blocks, each input data block may be processed individually (step 304), which may include temporarily storing an original input data block (step 306). In an optional step 308, bytes (comprising 8 bits) data may be divided into nibbles (comprising 4 bits). Nibbles may be valued 0-15. In an embodiment, the encoding algorithm may be configured to determine the frequency of each data unit (e.g. symbol, byte value, or nibble value) in the input data block and to order the determined frequencies in a sequence of values in a hierarchical order (e.g. increasing, alphabetical or any other suitable order) of the symbol, byte value, or nibble value.

For example, an input data block formatted as a sequence of byte values may include the following values:
input data block (byte values): (255, 216, 255, 224, 0, 16, 74, 70, 73, 70, 0, 1, 1, 0, 0, 1, 0, 1, 0, 0, 255, 219, 0, 67, 0, 3, 2, 2, 3, 2, 2, 3, 3, 3, 3, 4, 3, 3, 4, 5, 8, 5, 5, 4, 4, 5, 10, 7, 7, 6, 8, 12, 10, 12, 12, 11, 10, 11, 11, 13, 14, 18, 16, 13, 14, 17, 14, 11, 11, 16, 22, 16, 17, 19, 20, 21, 21, 21, 12, 15, 23, 24, 22, 20, 24, 18, 20, 21, 20, 255, 219, 0, 67, 1, 3, 4, 4, 5, 4, 5, 9, 5, 5, 9, 20, 13, 11, 13, 20, 20, 20, 20, 20, 20, 20, 20, 20, 20, 20, 20, 20, 20, 20, 20, 20, 20, 20, 20)
   The result of dividing the byte values into nibble values is a different representation of the same input data block, which may look as follows:
input data block (nibble values): (15, 15, 13, 8, 15, 15, 14, 0, 0, 0, 1, 0, 4, 10, 4, 6, 4, 9, 4, 6, 0, 0, 0, 1, 0, 1, 0, 0, 0, 0, 0, 1, 0, 0, 0, 1, 0, 0, 0, 0, 15, 15, 13, 11, 0, 0, 4, 3, 0, 0, 0, 3, 0, 2, 0, 2, 0, 3, 0, 2, 0, 2, 0, 3, 0, 3, 0, 3, 0, 3, 0, 4, 0, 3, 0, 3, 0, 4, 0, 5, 0, 8, 0, 5, 0, 5, 0, 4, 0, 4, 0, 5, 0, 10, 0, 7, 0, 7, 0, 6, 0, 8, 0, 12, 0, 10, 0, 12, 0, 12, 0, 11, 0, 10, 0, 11, 0, 11, 0, 13, 0, 14, 1, 2, 1, 0, 0, 13, 0, 14, 1, 1, 0, 14, 0, 11, 0, 11, 1, 0, 1, 6, 1, 0, 1, 1, 1, 3, 1, 4, 1, 5, 1, 5, 1, 5, 0, 12, 0, 15, 1, 7, 1, 8, 1, 6, 1, 4, 1, 8, 1, 2, 1, 4, 1, 5, 1, 4, 15, 15, 13, 11, 0, 0, 4, 3, 0, 1, 0, 3, 0, 4, 0, 4, 0, 5, 0, 4, 0, 5, 0, 9, 0, 5, 0, 5, 0, 9, 1, 4, 0, 13, 0, 11, 0, 13, 1, 4, 1, 4, 1, 4, 1, 4, 1, 4, 1, 4, 1, 4, 1, 4, 1, 4, 1, 4, 1, 4, 1, 4, 1, 4, 1, 4, 1, 4, 1, 4, 1, 4, 1, 4, 1, 4, 1, 4)
   As a result of this step, the input data block has become twice as long (256 nibbles instead of 128 bytes), but the range of values has become smaller (0-15 instead of 0-255). In some embodiments, the nibbles may be temporarily stored or processed as bytes with values 0-15 or even as integers of 4 bytes or 8 bytes. The efficiency may depend on the used hardware and/or software.

The ordered sequence corresponding to the permutation represented by the input data block may be the result of an ordering process. This ordered sequence may also be referred to as an ordered data block, which may look as follows:
ordered data block (nibble values): (0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 1, 2, 2, 2, 2, 2, 2, 3, 3, 3, 3, 3, 3, 3, 3, 3, 3, 3, 3, 4, 4, 4, 4, 4, 4, 4, 4, 4, 4, 4, 4, 4, 4, 4, 4, 4, 4, 4, 4, 4, 4, 4, 4, 4, 4, 4, 4, 4, 4, 4, 4, 4, 4, 4, 4, 4, 4, 5, 5, 5, 5, 5, 5, 5, 5, 5, 5, 5, 5, 6, 6, 6, 6, 6, 7, 7, 7, 8, 8, 8, 8, 8, 9, 9, 9, 10, 10, 10, 10, 11, 11, 11, 11, 11, 11, 11, 11, 12, 12, 12, 12, 13, 13, 13, 13, 13, 13, 13, 14, 14, 14, 14, 15, 15, 15, 15, 15, 15, 15, 15, 15)

The input data block and the ordered data block may be used to determine a permutation index. In some embodiments, the permutation index may be determined based on the data block alone, as was explained above with reference to FIG. 2A.

In a next step, an ordered data block may subsequently be processed by a frequency determination process to define an ordered sequence of elements, where each element of the ordered sequence defines the number of values associated with the position in the sequence (step 310). In an embodiment, the frequency data may be determined based on the input data block (e.g. in byte or nibble representation), rather than the ordered data block. The result of the frequency counting process is a frequency data block, which may look as follows:
frequency data block (nibble values): (86, 50, 6, 12, 38, 12, 5, 3, 5, 3, 4, 8, 4, 7, 4, 9)
   A frequency data block may be formatted to define an ordered sequence of elements, wherein the first element indicates that the original data block contains 86 times the nibble value 0, the second element indicates that the original data block contains 50 times the nibble value 1, the third element indicates that the original data block contains 6 times the nibble value 2, the forth element indicates 12 times the nibble value 3, etc. The length of the frequency data block may correspond to the range of possible values. For example, for nibbles encoding 16 possible values (e.g. range 0-15), the length of the frequency data block may be 16 values, while for bytes encoding 256 possible values (e.g. range 0-255), the length of the frequency data block may be 256 possible values. The range of the values in the frequency data block may correspond to the number of data units in the data block, e.g. for a data block of 256 nibbles, the range of values in the frequency data block may be 0-256; while for a data block of 128 bytes the range of values in the frequency data block may be 0-128. The sum of all elements in the frequency data block may correspond to the number of data units in the data block.

The ordered data block and/or the frequency data block may be temporary stored so that it can be used as input data to further encoding steps. In some embodiments, the frequency data block may be constructed without first (explicitly) constructing an ordered data block.

In some embodiments, before or during determining frequencies in the input data block, data units may be subdivided into smaller data units, e.g., words (typically 32 or 64 bits) may be converted into bytes, or bytes (i.e. 8-bit values) may be converted into nibbles (i.e. 4-bit values) (step 308). Alternatively, ascii representation may be used. For example, the number 255 may be may be represented by 0xFF in hexadecimal notation. This hexadecimal number may be subsequently transformed into two ascii codes 70 70, i.e. the ascii code for the symbol F in decimal notation. Although such transformation would lead to block sizes that are twice the size of the original bock size, it nevertheless may lead to a substantial improvement in coding efficiency. This is due to the fact that that a byte value may represent 255 different numbers whereas the ascii code only 16 (namely the ascii codes for 0-9 and a-f). Consequently, frequencies need to be determined for only 16 values, instead of 256. This is mathematically equivalent to dividing bytes into nibbles, but may be more efficient to code or process.

In the next step, a permutation index of the input data block may be calculated by a first permutation function P1 using the input data block and, optionally, the ordered data block or the frequency data block as input (step 312). In the latter case, the permutation function may interpret the frequency data block as a data block comprising a sequence of: 86 zeroes, 50 ones, 6 twos, etc.

Alternatively, the encoding algorithm may check if the permutation index is already stored in an indexed list 328, which hereafter may be referred to as a permutation dictionary (step 318). In case the index is not stored in the permutation dictionary, the permutation index may be added to the permutation dictionary (step 324) and the newly created permutation dictionary index may be returned (step 326) and stored in an output data storage (step 318). In case the permutation index is already stored in the permutation dictionary, the permutation dictionary index may be returned (step 320) and stored in the output data storage (step 322).

In an embodiment, the frequency data may be stored directly in the output data storage. This is computationally efficient. In a different embodiment, the frequency data may be further compressed or encoded. This further compression or encoding may be based on the fact that the sum of the frequencies must be equal to the total number of data units (e.g. bytes or nibbles) in the data block.

For example, in the case of encoding 256 data units, a frequency count ranges in principle from 0-256. A fixed storage size would require at least 9 bits, i.e. more than 1 byte, to store each possible value. However, by treating the case where all data units are identical (i.e. one value appears 256 times, all other values appear 0 times) as a special case, the storage per frequency value can easily be reduced to 1 byte per frequency count.

In an embodiment, the lowest occurring frequency in a frequency data block may be subtracted from all frequencies in the frequency data block, and the thus reduced frequency values may be stored. These reduced frequency values may require less bits than the not-reduced frequency values to store, e.g. less than a full byte for a data block of length 256. Consequently, the reduced frequency values may be stored more efficiently, together with an indication of the amount of bits used to store the reduced frequency values. The original frequencies may be restored by adding the same amount to each frequency in the frequency data, such that the sum of all frequencies equals the number of data units in the data block, e.g. 256.

The difference between the highest and lowest frequency may be referred to as the frequency range. When the data resembles random data the frequencies will tend to the average value, e.g. 16 in the case of 256 nibbles encoding 16 possible values, and the frequency range will tend to one. This is particularly relevant when the data that is being processed is a compressed data file, e.g. a zip file or mp4 file. In these cases, it has been found that for about two thirds of data blocks comprising 256 nibbles, the frequency range is less than 16 and thus the frequency data could be encoded with only 4 bits per frequency. This is less than half the amount needed without any form of frequency data compression.

In an embodiment, instead of storing the frequencies in the output data storage, the frequencies may be stored in a frequency dictionary, and the output data storage may comprise a frequency dictionary index. Thus, the output data may comprise a permutation dictionary index and a, preferably compressed, frequency data block; or a permutation dictionary index and a frequency dictionary index; or a permutation index and a frequency dictionary index.

As was discussed above, the permutation index may be either stored in the output data storage, or in a permutation dictionary. In an embodiment, the permutation index Pᵢ may be stored in the following format:

| Byte | Byte | Byte | Byte | Byte | Byte | Byte | Byte | | Byte |
|---|---|---|---|---|---|---|---|---|---|
| 1 | 2 | 3 | 4 | 5 | 6 | 7 | 8 | . . . | N + 1 |
| Length | Pᵢ MSB | | | | | | | | Pᵢ LSB |

The first byte may indicate the length of the permutation index Pᵢ in bytes, and the following bytes may hold the value of the permutation index, preferably in big-endian format. The maximum size in bytes of the permutation index may be given by ceil(log₂ Pₘₐₓ/8), where ceil(x) denotes the ceiling function which maps x to the least integer greater than or equal to x. The maximum size depends on the block size as discussed above. Consequently, the size of the stored permutation index may vary from 2 bytes (including length byte) up to ceil(log₂ Pₘₐₓ/8)+1 bytes. In some embodiments, the length may be encoded using more than 1 byte. In some embodiments the length may be encoded in other units than bytes, such as bits or multiples of bytes.

In a typical embodiment, only a small number of all possible permutation indices may be used. For example, with 2³² permutations of 128 bytes (256 nibbles) of data, at least 500 GB of data may be encoded. In practice, the amount of encoded data may be even larger, as permutation indices may be reused several times, as was explained above with reference to FIG. 1. Therefore a limited permutation dictionary index size suffices in practice. For example, the permutation index size may be fixed at 4 bytes (32 bits), i.e., the size of an integer in many computer systems. The permutation dictionary index size may also be defined in a header of an encoded file. To encode even larger amounts of data, in some embodiments a second or further permutation dictionary may be used.

The permutation dictionary index Dₚᵢ and the frequency data D_{f} may be stored in a data package as follows:

| Byte | Byte | | Byte | Byte | Byte | Byte | Byte |
|---|---|---|---|---|---|---|---|
| 1 | 2 | . . . | N + 1 | N + 2 | N + 3 | N + 4 | N + 5 |
| Pre- | D_{f} Byte 1 | | D_{f} Byte N | Dₚᵢ MSB | | | Dₚᵢ LSB |
| amble | | | | | | | |

The first byte may be a preamble, and will be discussed in more detail below. The next N bytes may store the frequency data. N may be fixed, for example at 16 bytes, or may be a variable number of bytes, for example when compression as explained above has been used. The last 4 bytes may comprise the permutation dictionary index, preferably stored in big-endian format. In other embodiments, the order of preamble, frequency data, and permutation dictionary index may be different.

Alternatively, the permutation index and a frequency dictionary index may be stored in the data output storage in the following way:

| Byte | Byte | Byte | . . . | Byte | Byte | Byte | Byte | Byte |
|---|---|---|---|---|---|---|---|---|
| 1 | 2 | 3 | | N + 2 | N + 3 | N + 4 | N + 5 | N + 6 |
| Pre- | Pᵢ | Pᵢ Byte | | Pᵢ Byte | Dᵢ MSB | | | Dᵢ LSB |
| amble | Length | 1 | | N | | | | |

The preamble may be used to store information about the data package, such as the length of the frequency data or information about the permutation dictionary index. In an embodiment, the preamble byte may contain 8 bits as follows:

| Bit 8 | Bit 7 | Bit 6 | Bit 5 | Bit 4 | Bit 3 | Bit 2 | Bit 1 |
|---|---|---|---|---|---|---|---|
| EOB | Dᵢ Auto | Dₛ dic- | Pᵢ Lim- | Not | Dₛ | Dₛ | Dₛ |
| | Inc. | tionary | ited | Used | Length | Length | Length |
| | | | | | Bit 3 | Bit 2 | Bit 1 |

Bit 8: EOB. This can be an End of Blocks marker. Because not all files or data streams are (evenly) divisible by the block size, there is a possibility of a number of bytes remaining after encoding the maximum number of complete blocks. This number is maximally the block size—1. This bit may indicate that the following bytes to EOF (end of file) are the remaining bytes that have to be stored at the end of all the replacement blocks.

Bit 7: Dᵢ Auto Inc. This bit may indicate that there is no permutation dictionary Index present. This is the case if the permutation dictionary Index is 1 higher than the permutation dictionary Index of the previous block. This may occur frequently e.g. when the dictionary is still being built and comprises only relatively few permutation indices. In this case, it may not be necessary to include the permutation dictionary index because the decoder knows the previous one and only has to increment that by one. In those cases, this will save extra bytes within the data package.

Bit 6: Dₛ Dictionary. This bit may indicate whether the dictionary contains permutation indices or datasets, e.g. frequency data. As was explained above, it is possible to either store the permutation index into a dictionary and the frequency data in the output data package, or to store the frequency data into a dictionary and store the permutation index in the data output package. In case both the permutation index and the frequency data are stored in dictionaries, a preamble byte may typically be left out.

Bit 5: Pᵢ Limited. This bit may indicate whether the permutation index has been adjusted, e.g. by a calculation as follows. In an embodiment, a maximum permutation index P_{i,max} may be determined, and permutation indices Pᵢ larger than half the maximum permutation index may be replaced by P_{i,max}−Pᵢ. If this is the case, an inverse calculation may have to be performed on the permutation index pointed to by the dictionary index.

Bit 4: Not Used. One or more bits in the preamble may have no meaning, or be reserved for future use.

Bit 3-1: Dₛ Length. These bits may encode a value in the range 0-7. These 3 bits may indicate the length for a dataset element. For example, the dataset (Dₛ) length in bytes may be calculated with ((Length+1)×16)/8, or may be stored in a look-up table with 8 or less entries. When the data output package comprises the permutation index (rather than the permutation dictionary index) these bits may remain unused if the permutation index package comprises a length byte. It is also possible to use the Length bits, and optionally the ‘unused’ bit 4, to encode the length of the permutation index and leave out the length byte from the permutation index package. In that case, the length of the permutation index may be encoded in e.g. multiples of 8 bytes. Combinations are also possible, e.g. using the preamble length bits if the permutation index has a length of less than 16 bytes, and the permutation index package length byte if the permutation index has a length of 16 bytes or more. This may be indicated by e.g. setting the length bits in the preamble byte to zero.

In other embodiments, the data package may comprise a permutation dictionary index and a frequency dictionary index. In such an embodiment, the preamble may be left out. In that case, the number of data packages and/or the (unencoded) file length may be encoded in a file header.

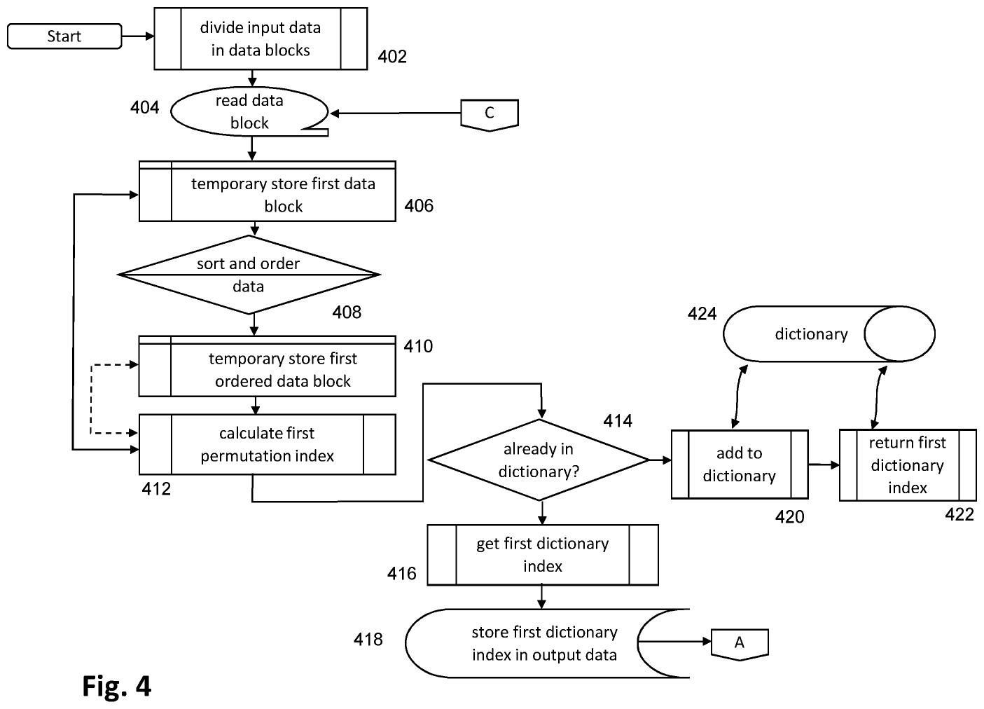

FIG. 4-6 depict flow diagrams of different phases of an alternative encoding process according to an embodiment of the invention. FIG. 4 depicts a first phase of the encoding process, wherein in a first step 402 a data file or stream may be divided into data blocks of a predetermined length N. Here, each block may be formatted as an array of N data units, wherein the data units may represent a symbol (letters, numbers, etc.) that can be ordered, e.g. ascii symbols representing numbers and letters, byte values representing a value in the range 0-255, etc. For example, the block may define an array of 256 bytes (N=256). Each byte value may represent a value between 0 and 255. If the length of the data block is not equal to a multiple of N, the remaining data units may be stored in a temporary buffer. The remaining bytes may be added to the final result when all blocks are processed. For example, a file of 12000 bytes may result into 46 blocks of 256 bytes to be processed, wherein the remaining 224 bytes may be temporary stored.

After dividing the data file or data stream in data blocks, each data block may be processed individually (step 404), which may include temporarily storing an original first data block (step 406), ordering the data units in the first data block based on their value or symbol type (step 408) and storing the ordered data units as a first ordered data block (step 410). An algorithm for executing the ordering step 408 may be configured to process data units of a data block. In an embodiment, the algorithm may be configured to determine the frequency of each data unit (e.g. symbol or byte value) in the data block and to order the determined frequencies in a sequence of values in a hierarchical order (e.g. increasing, alphabetical or any other suitable order). For example, a first data block formatted as a sequence of byte values may include the following values:
first input data block: (255, 216, 255, 224, 0, 16, 74, 70, 73, 70, 0, 1, 1, 0, 0, 1, 0, 1, 0, 0, 255, 219, 0, 67, 0, 3, 2, 2, 3, 2, 2, 3, 3, 3, 3, 4, 3, 3, 4, 5, 8, 5, 5, 4, 4, 5, 10, 7, 7, 6, 8, 12, 10, 12, 12, 11, 10, 11, 11, 13, 14, 18, 16, 13, 14, 17, 14, 11, 11, 16, 22, 16, 17, 19, 20, 21, 21, 21, 12, 15, 23, 24, 22, 20, 24, 18, 20, 21, 20, 255, 219, 0, 67, 1, 3, 4, 4, 5, 4, 5, 9, 5, 5, 9, 20, 13, 11, 13, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 255, 192, 0, 17, 8, 3, 132, 6, 64, 3, 1, 34, 0, 2, 17, 1, 3, 17, 1, 255, 196, 0, 31, 0, 0, 1, 5, 1, 1, 1, 1, 1, 1, 0, 0, 0, 0, 0, 0, 0, 0, 1, 2, 3, 4, 5, 6, 7, 8, 9, 10, 11, 255, 196, 0, 181, 16, 0, 2, 1, 3, 3, 2, 4, 3, 5, 5, 4, 4, 0, 0, 1, 125, 1, 2, 3, 0, 4, 17, 5, 18, 33, 49, 65, 6, 19, 81, 97, 7, 34, 113, 20, 50, 129, 145, 161, 8, 35)
   The result of the ordering process is an ordered data block, which may look as follows:
first ordered data block: (0, 0, 0, 0, 0, 0, 0, 0, 0, 0, 0, 0, 0, 0, 0, 0, 0, 0, 0, 0, 0, 0, 0, 0, 0, 0, 0, 0, 1, 1, 1, 1, 1, 1, 1, 1, 1, 1, 1, 1, 1, 1, 1, 1, 1, 1, 1, 2, 2, 2, 2, 2, 2, 2, 2, 2, 3, 3, 3, 3, 3, 3, 3, 3, 3, 3, 3, 3, 3, 3, 3, 3, 3, 4, 4, 4, 4, 4, 4, 4, 4, 4, 4, 4, 4, 5, 5, 5, 5, 5, 5, 5, 5, 5, 5, 5, 5, 5, 6, 6, 6, 6, 7, 7, 7, 7, 8, 8, 8, 8, 8, 9, 9, 9, 10, 10, 10, 10, 11, 11, 11, 11, 11, 11, 11, 12, 12, 12, 12, 13, 13, 13, 13, 14, 14, 14, 15, 16, 16, 16, 16, 16, 17, 17, 17, 17, 17, 17, 18, 18, 18, 19, 19, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 20, 21, 21, 21, 21, 22, 22, 23, 24, 24, 31, 33, 34, 34, 35, 49, 50, 64, 65, 67, 67, 70, 70, 73, 74, 81, 97, 113, 125, 129, 132, 145, 161, 181, 192, 196, 196, 216, 219, 219, 224, 255, 255, 255, 255, 255, 255, 255)
   This ordered data block may be referred to as a first ordered data block. In some embodiments, this ordered data block may not need to be constructed explicitly. The ordered data block or the first input data block may be the input of a frequency counting process. The result of the frequency counting process is a frequency data block, which may look as follows:
first frequency data block: (28, 19, 9, 17, 12, 13, 4, 4, 5, 3, 4, 7, 4, 4, 3, 1, 5, 6, 3, 2, 56, 4, 2, 1, 2, 0, 0, 0, 0, 0, 0, 1, 0, 1, 2, 1, 0, 0, 0, 0, 0, 0, 0, 0, 0, 0, 0, 0, 0, 1, 1, 0, 0, 0, 0, 0, 0, 0, 0, 0, 0, 0, 0, 0, 1, 1, 0, 2, 0, 0, 2, 0, 0, 1, 1, 0, 0, 0, 0, 0, 0, 1, 0, 0, 0, 0, 0, 0, 0, 0, 0, 0, 0, 0, 0, 0, 0, 1, 0, 0, 0, 0, 0, 0, 0, 0, 0, 0, 0, 0, 0, 0, 0, 1, 0, 0, 0, 0, 0, 0, 0, 0, 0, 0, 0, 1, 0, 0, 0, 1, 0, 0, 1, 0, 0, 0, 0, 0, 0, 0, 0, 0, 0, 0, 0, 1, 0, 0, 0, 0, 0, 0, 0, 0, 0, 0, 0, 0, 0, 0, 0, 1, 0, 0, 0, 0, 0, 0, 0, 0, 0, 0, 0, 0, 0, 0, 0, 0, 0, 0, 0, 1, 0, 0, 0, 0, 0, 0, 0, 0, 0, 0, 1, 0, 0, 0, 2, 0, 0, 0, 0, 0, 0, 0, 0, 0, 0, 0, 0, 0, 0, 0, 0, 0, 0, 0, 1, 0, 0, 2, 0, 0, 0, 0, 1, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 7)
   This frequency data block may be referred to as a first frequency data block. A frequency data block may be formatted to define an ordered sequence of elements, wherein the first element indicates that the original (input) data block contains 28 times the byte value 0, the second element indicates that the original data block contains 19 times the byte value 1, the third element indicates that the original data block contains 9 times the byte value 2, the forth elements 17 times the byte value 3, etc. The first data block and/or the first frequency data block may be temporarily stored so that it can be used as input data to further encoding steps (step 410). It is worth noting that the (first) frequency data block comprises the same information as the (first) ordered data block, but in a different encoding.

In some embodiments, before ordering the first data block, byte values may be converted to ascii code. For example, the number 255 may be may be represented by 0xFF in hexadecimal notation. This hexadecimal number may be subsequently transformed into two ascii codes 70 70, i.e. the ascii code for the symbol F in decimal notation. Although such transformation would lead to block sizes that are twice the size of the original bock size, it nevertheless may lead to a substantial improvement in coding efficiency. This is due to the fact that that a byte value may represent 255 different numbers whereas the ascii code only 16 (namely the ascii codes for 0-9 and A-F).

In the next step, a first permutation index of the first data block may be calculated by a first permutation function P1 using the first data block and the first ordered data block as input (step 412). Here, the permutation function may interpret the first ordered data block as a data block comprising a sequence of: 28 zeroes, 19 ones, 9 twos, etc. The encoding algorithm may check if the first permutation index is already stored in an indexed list, which hereafter may be referred to as a permutation dictionary (step 414). In case the index is not stored in the permutation dictionary, the first permutation index may be added to the permutation dictionary (step 420) and the newly created permutation dictionary index may be returned (step 422) and stored in an output data storage (step 418). In case the permutation index is already stored in the dictionary, the permutation dictionary index may be returned (step 416) and stored in the output data storage (step 418).

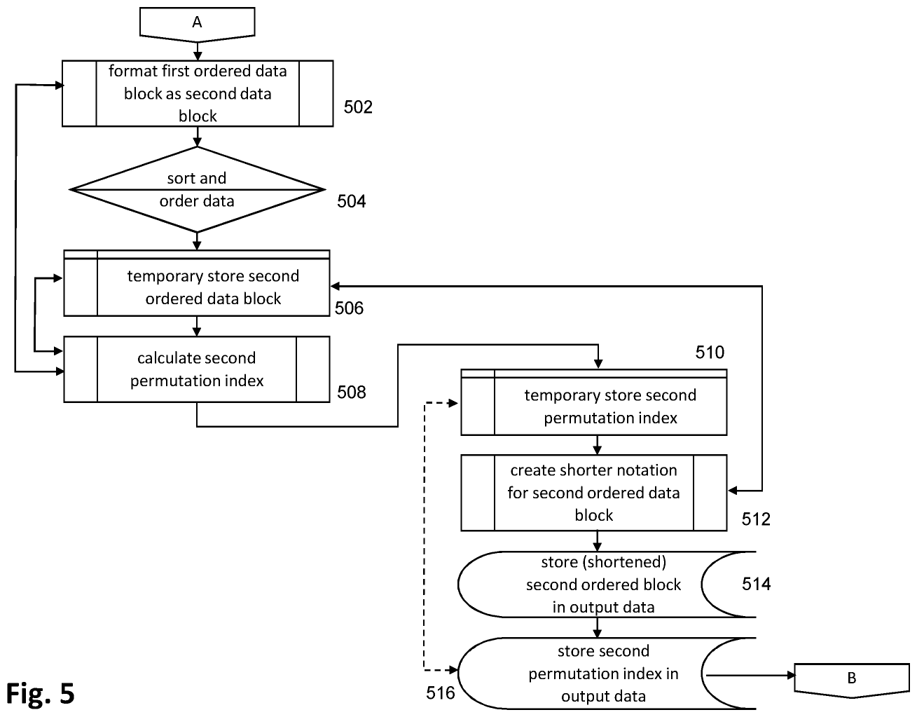

In an embodiment, the encoding process may comprise a second phase. Such a second phase of the encoding process is shown in FIG. 5. In this phase, the first frequency data block may be further processed. The encoding algorithm may first transform the first frequency data block into a format of a byte array (i.e. an array of N bytes each having a certain byte value) that is similar to the data format of the (original) first data block (step 502). This reformatted first frequency data block may be referred to as a second data block. In some embodiments, reformatting may not be necessary and the second data block may be identical to the frequency data block.

When transforming the first frequency data block into a second data block of a byte array format, two different situations may be considered. The first frequency data block may comprise only one non-zero element, which may be treated as a special case (as will be discussed later). Otherwise, the first frequency data block includes different elements with non-zero values (e.g. the case in the example of the first frequency data block mentioned above). In that case, the encoding algorithm just transforms the values of the elements of the first frequency data block in to byte values resulting in a second data block comprising a sequence of the following byte values:
second data block: (28, 19, 9, 17, 12, 13, 4, 4, 5, 3, 4, 7, 4, 4, 3, 1, 5, 6, 3, 2, 56, 4, 2, 1, 2, 0, 0, 0, 0, 0, 0, 1, 0, 1, 2, 1, 0, 0, 0, 0, 0, 0, 0, 0, 0, 0, 0, 0, 0, 1, 1, 0, 0, 0, 0, 0, 0, 0, 0, 0, 0, 0, 0, 0, 1, 1, 0, 2, 0, 0, 2, 0, 0, 1, 1, 0, 0, 0, 0, 0, 0, 1, 0, 0, 0, 0, 0, 0, 0, 0, 0, 0, 0, 0, 0, 0, 0, 1, 0, 0, 0, 0, 0, 0, 0, 0, 0, 0, 0, 0, 0, 0, 0, 1, 0, 0, 0, 0, 0, 0, 0, 0, 0, 0, 0, 1, 0, 0, 0, 1, 0, 0, 1, 0, 0, 0, 0, 0, 0, 0, 0, 0, 0, 0, 0, 1, 0, 0, 0, 0, 0, 0, 0, 0, 0, 0, 0, 0, 0, 0, 0, 1, 0, 0, 0, 0, 0, 0, 0, 0, 0, 0, 0, 0, 0, 0, 0, 0, 0, 0, 0, 1, 0, 0, 0, 0, 0, 0, 0, 0, 0, 0, 1, 0, 0, 0, 2, 0, 0, 0, 0, 0, 0, 0, 0, 0, 0, 0, 0, 0, 0, 0, 0, 0, 0, 0, 1, 0, 0, 2, 0, 0, 0, 0, 1, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 7)

Thereafter, the byte values of the second data block may be processed. This ordering process may be similar to the one described above with reference to the first data block. Again, the second ordered data block may not need to be constructed explicitly. The result of the ordering may be a second ordered data block that has the same data format as the first ordered data block:
Second ordered data block: (0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 1, 1, 1, 1, 1, 1, 1, 1, 1, 1, 1, 1, 1, 1, 1, 1, 1, 1, 1, 1, 1, 1, 1, 2, 2, 2, 2, 2, 2, 2, 2, 3, 3, 3, 4, 4, 4, 4, 4, 4, 5, 5, 6, 7, 7, 9, 12, 13, 17, 19, 28, 56)

In an embodiment, the processing may include determining the frequency of each byte value in the block and ordering the values of the determined frequencies in a sequence of values of increasing order of byte value (step 504). The result of the ordering may be a second frequency data block that has the same data format as the first frequency data block:
Second frequency data block: (204, 23, 8, 3, 6, 2, 1, 2, 0, 1, 0, 0, 1, 1, 0, 0, 0, 1, 0, 1, 0, 0, 0, 0, 0, 0, 0, 0, 1, 0, 0, 0, 0, 0, 0, 0, 0, 0, 0, 0, 0, 0, 0, 0, 0, 0, 0, 0, 0, 0, 0, 0, 0, 0, 0, 0, 1, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0)

The second frequency data block may be temporarily stored for further processing (step 506). Thereafter, the second data block and, optionally, the second ordered data block and/or the second frequency data block may be used to determine a second permutation index (step 508), which may also be stored for further processing (step 510). In case the second frequency data block is provided to the permutation function, the permutation function may interpret the second frequency data block as a data block comprising a sequence of 204 zeroes, 23 ones, 8 twos, etc. The length of the second permutation index may be variable, so that only the number of bytes needed to store the index are stored. Alternatively, the second permutation index may be stored in a permutation dictionary. This may either be the same permutation dictionary as the permutation dictionary storing the first permutation index, or a different permutation dictionary. Because of the high redundancy in the second frequency data set (comprising at most 23 distinct values for an input data block of length 256), the second permutation index may be relatively small, as was explained above with reference to FIG. 1.

Further, the algorithm may create a shorter notation (a different data format, which may be referred to as a partition data format) for the second frequency data block (step 512). As was just mentioned, the second frequency data block may have a high redundancy, which may thus be reduced. In particular, the number of zeroes may be expected to be relatively high. Here, the partition data format may include two byte values for each non-zero element in the second frequency data block: a first byte value identifying a location n in the ordered sequence (n=1, . . . , N) and a second byte value identifying the number of bytes that have a byte value equal to n. Hence, only the non-zero elements are identified in the partition data format, all other elements are zero. For example, the partition of the above-mentioned second ordered data block may look as follows:
Partition of second frequency data block: (0, 204, 1, 23, 2, 8, 3, 3, 4, 6, 5, 2, 6, 1, 7, 2, 9, 1, 12, 1, 13, 1, 17, 1, 19, 2, 28, 1, 56, 1)

Thereafter, the partition and the second permutation index may be stored in the output data (steps 414,416), together with the dictionary index, in a new data block, which may be referred to as an encoded data block or a data key.

Special cases may be handled separately. For example, the first frequency data block may include only one element with a non-zero value, as in the following example:
First frequency data block: (0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 256)

The non-zero value must be equal to the block size N. Then, the second block may be obtained by a transformation resulting in a second data block wherein the value 256 has been replaced by, for example, the value 0×01=1:
Second data block: (0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 0, 1)

As the sum of the values in the second data block is not equal to 256, the algorithm may determine that the single non-zero value should be equal to 256.

Other encodings are also possible, provided that the data block can be distinguished from other potentially occurring data blocks. This may e.g. be achieved by ensuring that the sum of elements is not equal to, and preferably greater than, the block size N.

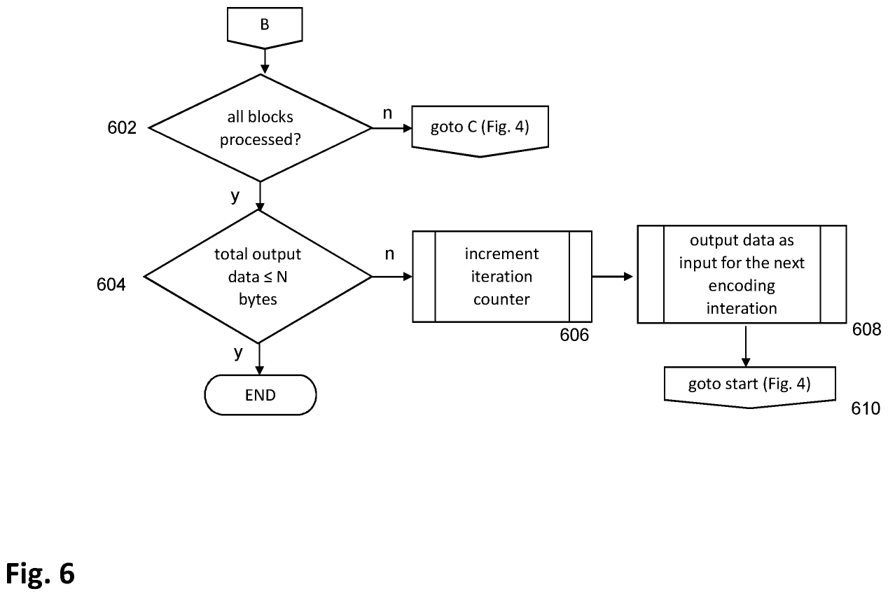

The block encoding scheme may process multiple blocks forming a large data file according to the flow diagram of FIG. 6. Here, the block encoding scheme of FIGS. 4 and 5 may be executed in a loop until all data blocks of the data file are encoded into encoded data blocks, which may be stored as output data in a memory (step 602). If all data blocks are processed, then the algorithm checks if the size of the output data (i.e. the size of all encoded blocks together) is smaller (or equal to or smaller) than a certain size of N bytes, e.g. 256 bytes. If this is not the case, an iteration counter i may be increased (step 604) and the encoding algorithm will start its next iteration using the output data as input data (step 608). During each iteration i (1=1, . . . , k) the dictionary will grow and the size of the output data will decrease. This process may be stopped if the size of the output data is smaller than the size of a data block (e.g. 256 bytes). Hence, after k iterations the block encoding process may stop wherein the resulting output data represent a data key of a predetermined size, e.g. 256 bytes or less. The data key may have a data format that is similar to the data format of an encoded data block as described with reference to FIG. 5.

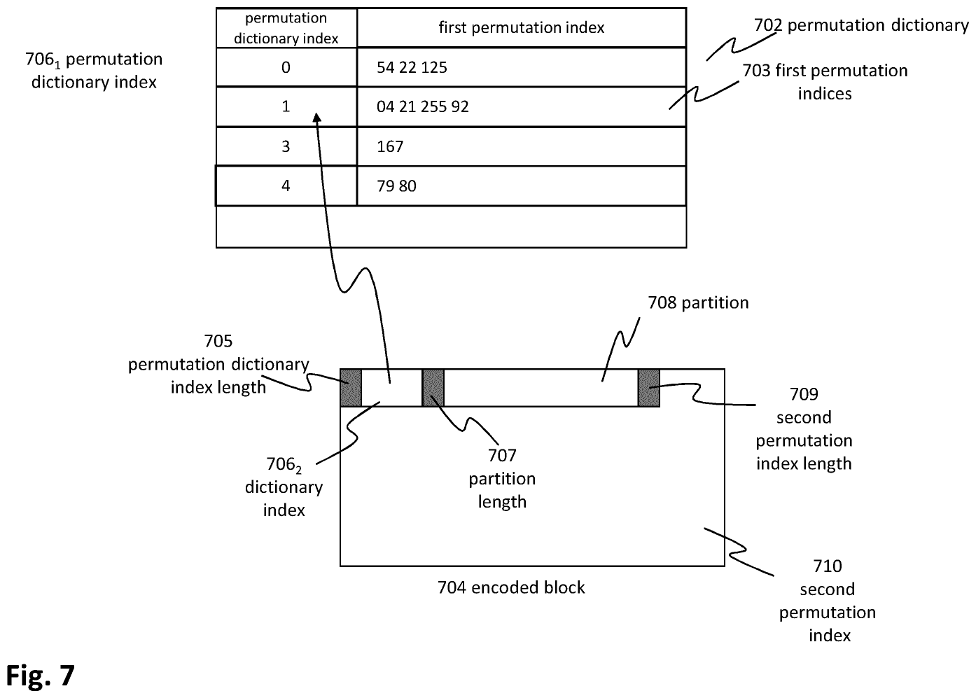

FIG. 7 depicts the result of the block encoding process as described with reference to FIG. 2-5. As described above, the encoder regards data blocks as a permutation of an ordered sequence of data units, wherein the permutation can be identified by a permutation index. Based on the permutation (a data block) and, optionally, the ordered sequence (an ordered data block) or frequency data (a frequency data block), a first permutation function can compute the permutation index. In an alternative embodiment, the first permutation function may output the ordered sequence and the corresponding permutation index, as was discussed above with reference to FIG. 2A.

Similarly, based on the permutation index and the ordered sequence or the frequency data (which may be converted to an ordered sequence), a second permutation function may compute the permutation as shown in FIG. 2B. The encoding process encodes a data block (representing a sequence of data units) based on a permutation function that calculates a permutation index, which may be stored in a permutation dictionary 702. The result of the encoding process is an encoded data block 704 comprising data (e.g. bytes) which are formatted according to a certain data format. In an embodiment, the data format may include a number of data fields including (but not limited to) a (first) permutation dictionary index 706₁, a partition 708 and a (second) permutation index or a second permutation dictionary index associated with the partition 710.

The size of these data fields may be variable. Hence, for a decoder to decode an encoded block, the decoder needs to have information about the data fields, e.g. the length of data fields and/or a start or end of data fields. In an embodiment, the data block may include metadata that is required for decoding the encoded data block, e.g. information about the size of the data fields, e.g. size of the dictionary index data field 705, a size of the partition data field 707 and a size of the second permutation index data field 709. Alternatively, the metadata (or part of the metadata) may be collected and stored in a separate file associated with the encoded data block.

The dictionary index of the encoded data block may point to an index 706₂ in the dictionary 702, which is linked to a certain (first) permutation index 703. The partition and its associated permutation index represents encoded information that is needed to compute an ordered sequence (an order data block) for the first permutation index so that the original data block can be recovered in a decoding process. Thus, the partition and second permutation index form an efficient notation for the first ordered data block, which—together with the first permutation index—is needed to compute the original first data block (the permutation of the first ordered data block) using a permutation function as described with reference to FIGS. 2A and 2B. The encoding process may be configured to encode the data block into an encoded data block that is smaller than original data block.

Hence, the result of the full encoding process as described with reference to FIG. 3-6 may be a dictionary (an indexed list of permutation indices), a data key and iteration information for determining (or representing) the number of iterations. In an embodiment, the data format of the encoded data block may include a data field for storing the number of iterations or information for determining the number of iterations. In another embodiment, the number of iterations may be provided as information (e.g. a key or the like) in a data message that is separated from the data key. The dictionary and the data key may be used in a secure coding scheme, wherein a data source, e.g. a video server, may encode a large number of high-resolution video titles based on the encoding scheme as described with reference to FIG. 1-6. These video titles may be used to build a dictionary of permutation indices, preferably one (shared) dictionary for all video titles together, and a plurality of data keys, one for each video title. Data processing devices, e.g. video players, may be provided with a decoder and the dictionary and a data processing device may playback a video title by requesting a data key of the video title and restoring the original video data using the data key and the dictionary.

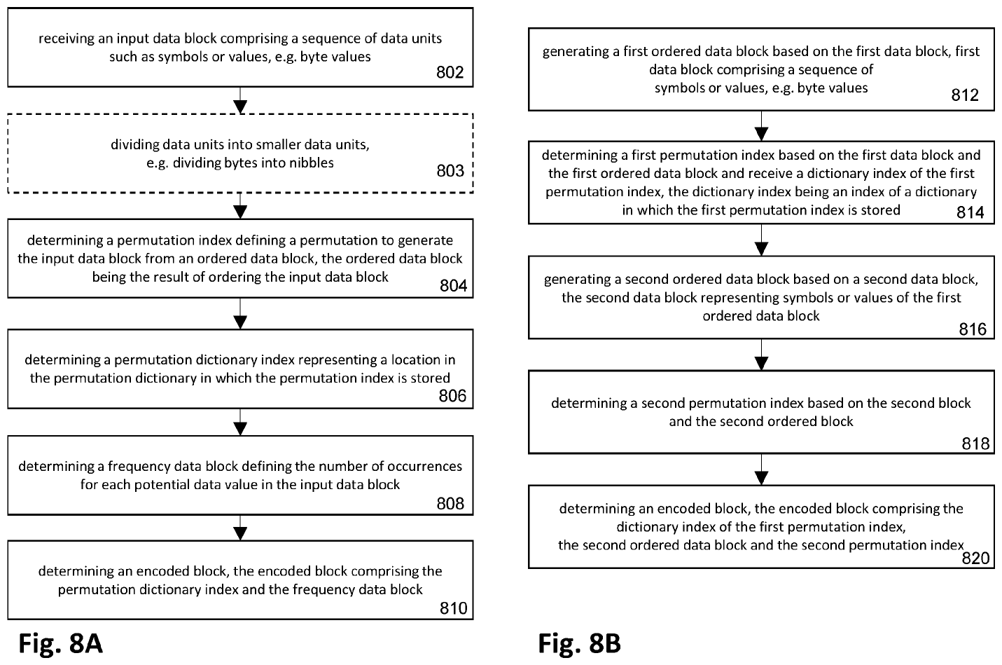

FIGS. 8A and 8B depict flow diagrams of at least part of a permutation-based encoding process according to embodiments of the invention. In particular, the flow diagrams depict the steps of encoding one of one or more data blocks, which may be generated by dividing a data file in a predetermined number of blocks of a predetermined size, e.g. N bytes or symbols.

In the flow diagram depicted in FIG. 8A, the coding scheme for encoding an input data block into an encoded data block may start with receiving an input data block comprising a sequence of data units such as symbols or values, e.g. byte values (step 802). In an optional step 803, the data units may be divided into smaller units, e.g. bytes (8-bit units) may be divided into nibbles (4-bit units). In a next step, a permutation index may be determined that defines a permutation generating the input data block as a permuted sequence of an ordered data block, where the ordered data block is the result of ordering the input data block (step 804). Preferably, the byte values are interpreted as natural numbers and the ordering is the standard (total) order on the natural numbers. The coding scheme may then determining a permutation dictionary index representing a location in the permutation dictionary in which the permutation index is stored (step 806). In a next step, a frequency data block may be determined that defines the number of occurrences for each potential data value in the input data block (step 808). Preferably, the number of occurrences for each potential data value in the input data block are determined and ordered in a sequence of values in a hierarchical order, e.g. increasing or decreasing order of the data value. In a next step, an encoded block may be determined, the encoded block comprising the dictionary index of the first permutation index and the frequency data block (step 810). Preferably, the frequency data block has been compressed.

It should be noted that the permutation dictionary index typically has a length of only a few bytes, e.g. 4 or 8 bytes. The frequency data block may be constructed in a way to be substantially shorter than the length of a data block, e.g. a frequency data for a block of 256 nibbles (encoding 128 bytes) may have a length of less than 16 bytes. Thus, an input data block of 128 bytes may result in an encoded block of e.g. 20 bytes. A plurality of such encoded data blocks may be concatenated into a data key. The data key may be further encoded in the same way, further reducing the size of the data key. The corresponding entry or entries in the permutation dictionary may be shared between various encoded files. In an embodiment, the permutation dictionary may be freely shared, while distribution of the data keys may be restricted. For example, the dictionary may be shared using a peer-to-peer network, which puts low demands on e.g. a central file server and is cheap to use, while the data keys may be distributed using a secure, but more expensive communication channel.

In the flow diagram depicted in FIG. 8B, the coding scheme for encoding a data block into an encoded data block may start with generating a first ordered data block based on the first data block (step 812), first data block comprising sequence of data units, symbols or values for example byte values. In a next step, a first permutation index based on the first data block and the first ordered data block may be determined and a dictionary index of the first permutation index may be retrieved, wherein the dictionary index is an index of a dictionary in which the first permutation index is stored (step 814). Further, a second ordered data block may be determined based on a second data block, wherein the second data block may represent symbols or values of the first ordered data block (step 816). A second permutation index may be determined based on the second block and the second ordered block (step 818) and an encoded block may be determined, wherein the encoded block comprises the dictionary index of the first permutation index, the second ordered data block and the second permutation index associated with the second ordered data block (step 820).

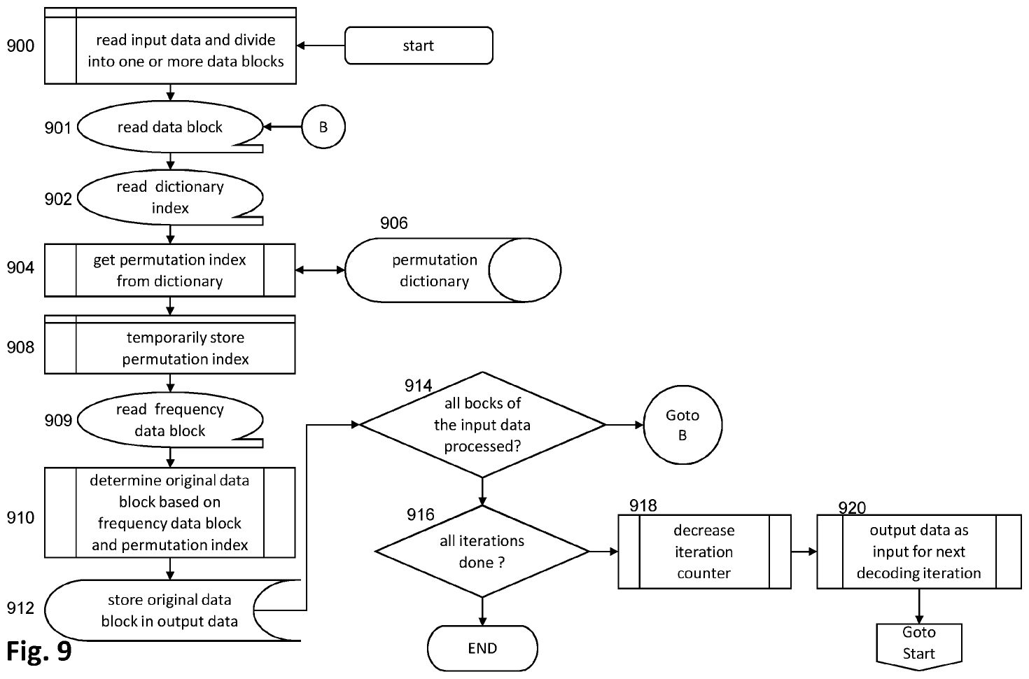

FIG. 9 describes a decoding process according to various embodiments of the invention. The decoding process may be executed by a decoder that is provided with a permutation dictionary comprising an indexed list of permutation indices which may be used by the decoder to decode a data key. The permutation dictionary stored in the memory of the decoder may comprise the same permutation indices as the permutation indices of the dictionary that was used by the encoder to generate the data key. For instance, the permutation dictionary in the decoder may be a copy of the permutation index in the encoder. The data key may be encoded according to the encoding process discussed with relation to FIG. 3.

The decoder may receive a data key having a data format that is known to the decoder. As a first step 900, the decoder may receive input data, a data key, and divide the input data into one or more blocks of N bytes. In case of a data key that has been encoded to contain less than N bytes, the decoder may take the data key as one data block. The one or more blocks may be processed according to the decoding process as described hereunder.

Similarly, if the input data is an intermediate result of the iterative decoding process (as described hereunder), the input data may be divided in multiple bocks and each of the blocks may be processed according to the decoding process in the subsequent steps.

The decoder may read a data block (step 901) and determine a permutation dictionary index from a first data field of the data block (step 902). The decoder may use the permutation dictionary index to retrieve a permutation index, which is stored in the permutation dictionary (steps 904, 906). The permutation dictionary index may be temporarily stored in a data buffer (step 908) for further processing. A next data field related to the (compressed) frequency data may be read by the decoder and—if necessary—the decoder may expand the compressed frequency data to a frequency data block, which may be stored in a data buffer (step 909).

Subsequently, an original data block may be determined based on a permutation function wherein the permutation index and the frequency data block, or an ordered data block based on the frequency data block, are provided as input data to the permutation function (step 910). The original data block may be stored as output data in a buffer (step 912).

In some embodiments, during encoding, byte values of a block may have been converted to nibbles or to ascii code before applying the block-encoding process. In that case, the data units of the decoded original data block may be nibbles or ascii codes. Hence, in that case, in order to restore the original data, the nibbles are joined together into bytes, or the ascii codes are first transformed back to byte values, before storing the decoded data block as output data.

Thereafter, the decoder may determine if all blocks of input data are processed (step 914). If this is not the case, then the decoder may start another decoding cycle in which a next encoded block is decoded following the steps above (i.e. steps 901 and further). If all blocks are decoded, then it may use the iteration information, e.g. an iteration counter, to check if all iterations are executed (step 916). If this is not the case, the iteration counter may be decreased (or increased) (step 918) and the decoded blocks in the output data may be used as input data and start the decoding process again (step 920). This process may be continued until the decoding process has executed the number of iterations that were necessary for the encoder to encode the data key. After the last iteration, the output data will represent the recovered original data file.

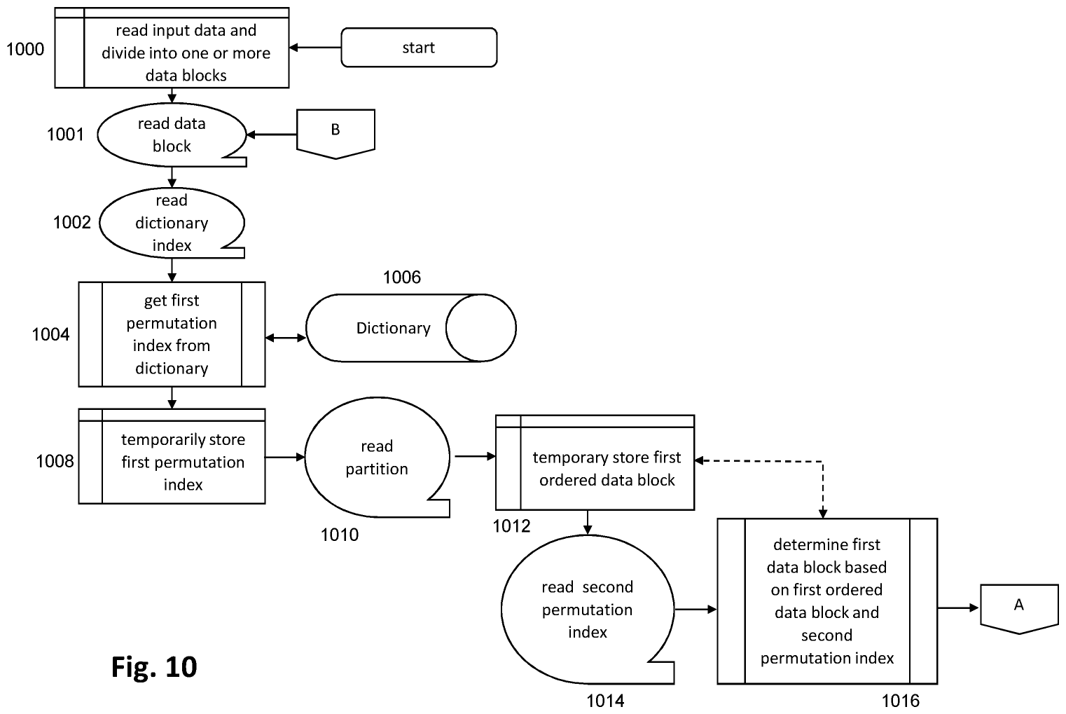

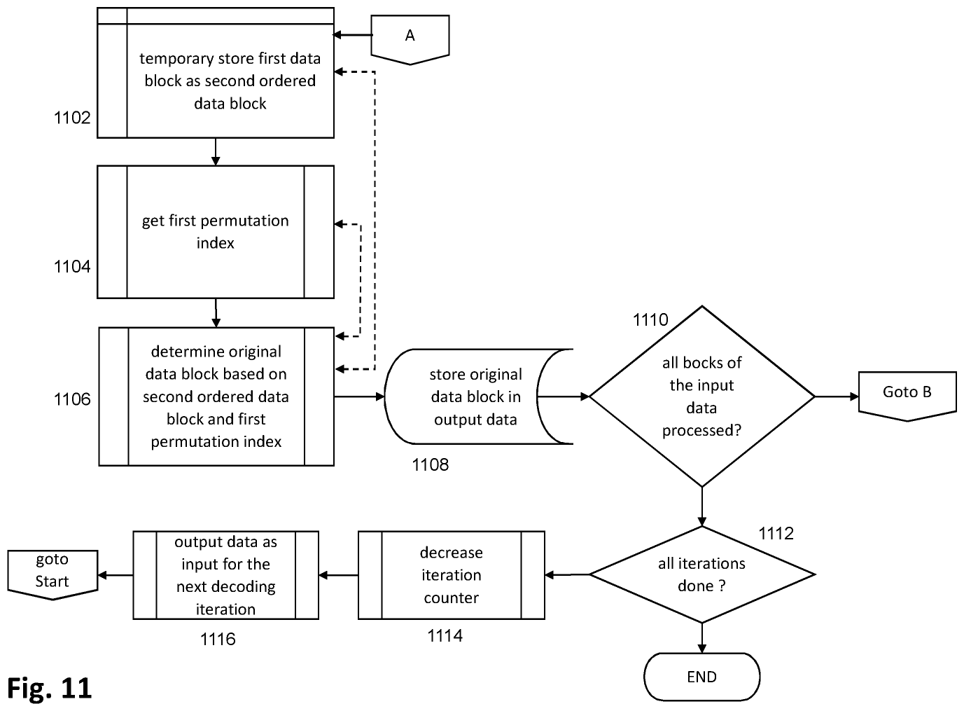

FIGS. 10 and 11 describe an alternative decoding process according to various embodiments of the invention. The decoding process may be executed by a decoder that is provided with a permutation dictionary comprising an indexed list of permutation indices which may be used by the decoder to decode a data key. The permutation dictionary stored in the memory of the decoder may comprise the same permutation indices as the permutation indices of the permutation dictionary that was used by the encoder to generate the data key. The data key may be encoded according to the encoding process discussed with relation to FIG. 4-6.

FIG. 10 depicts a first part of a decoding process according to an embodiment of the invention. In this phase, the decoder may compute an ordered data block which is needed to decode the original data using the permutation dictionary index in the data key.

The decoder may receive a data key having a data format that is known to the decoder. The data format may be similar to the data format described with reference to FIG. 7. As a first step 1000, the decoder may receive input data, a data key, and divide the input data into one or more blocks of N bytes. In case of a data key that has been encoded to contain less than N bytes, the decoder may take the data key as one data block. The one or more blocks may be processed according to the decoding process as described hereunder.

Similarly, if the input data is an intermediate result of the iterative decoding process (as described hereunder), the input data may be divided in multiple bocks and each of the blocks may be processed according to the decoding process in the subsequent steps.

The decoder may read a data block (step 1001) and determine a permutation dictionary index from a first data field of the data block (step 1002) and use the dictionary index to retrieve a first permutation index, which is stored in the dictionary (steps 1004, 1006). The permutation dictionary index may be temporarily stored in a data buffer (step 1008) for further processing. A next data field related to the partition may be read by the decoder and—if necessary—the decoder may expand the partition to first ordered data block, which may be stored in a data buffer (step 1012). A second permutation index associated with the partition may be read from the data key by the decoder (step 1014) and a permutation function may be used to determine a predetermined permutation, a first input data block, based on the stored first ordered data block and the second permutation index (step 1016). Further, the decoder may retrieve iteration information, i.e. information for determining the number of iterations the decoder has to execute to decode a data key into the original data file. Here, the first data block may be used by the decoder to restore the original data in a next phase of the decoding process, which is depicted in FIG. 11.

FIG. 11 depicts a flow diagram of a second part of a decoding process according to an embodiment of the invention. This process may start with temporarily storing the first data block as a second ordered data block (step 1102). Further, the first permutation index may be retrieved (step 1104) and an original (input) data block may be determined based on a permutation function wherein the second ordered block and the first permutation index are provided as input data to the permutation function (step 1106). The original data block may be stored as output data in a buffer (step 1108).

In some embodiments, during encoding, byte values of a block may have been converted to ascii before applying the block-encoding process. In that case, the data units of the decoded original data block may be ascii codes. Hence, in that case, in order to restore the original data, the ascii codes are first transformed back to byte values, before storing the decoded data block as output data.

Thereafter, the decoder may determine if all blocks of input data are processed (step 1110). If this is not the case, then the decoder may start another decoding cycle in which a next encoded block is decoded following the steps above (i.e. FIG. 10, steps 1001 and further). If all blocks are decoded, then it may use the iteration information, e.g. an iteration counter, to check if all iterations are executed (step 1112). If this is not the case, the iteration counter may be decreased (or increased) (step 1114) and the decoded blocks in the output data may be used as input data and start the decoding process again (step 1116). This process may be continued until the decoding process has executed the number of iterations that were necessary for the encoder to encode the data key. After the last iteration, the output data will represent the recovered original data file.

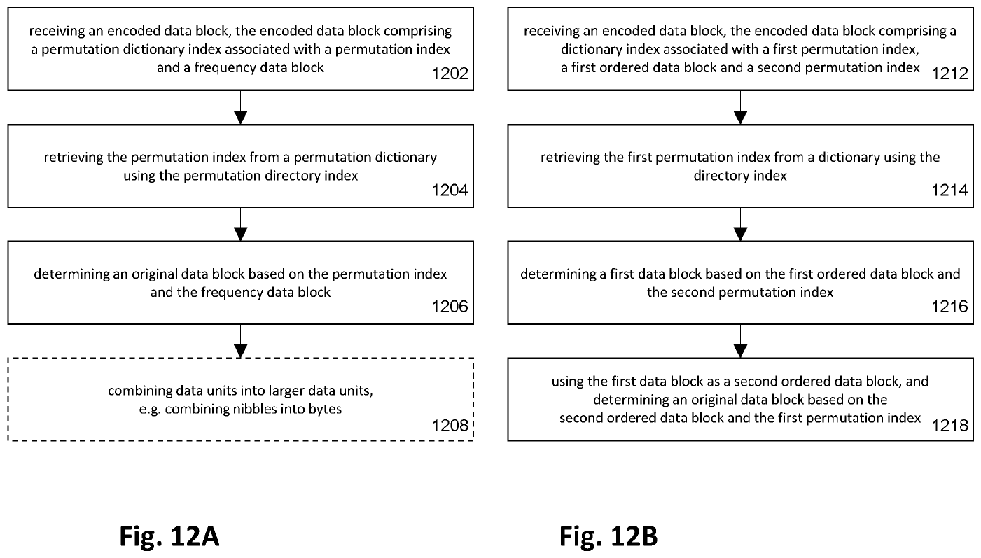

FIGS. 12A and 12B depict flow diagrams of at least part of a permutation-based decoding process according to an embodiment of the invention. In particular, the flow diagrams depict the steps of decoding an encoded data block into one or more data blocks on the basis of a dictionary of permutation indices.

In the flow diagram shown in FIG. 12A, the coding scheme for decoding an encoded data block may start with receiving an encoded data block, the encoded data block comprising a permutation dictionary index associated with a permutation index and a frequency data block (step 1202). Then, the permutation index may be retrieved from a permutation dictionary using the permutation dictionary index (step 1204). An original data block may then be determined based on the permutation index and the frequency data block or an ordered data block based on the frequency data block (step 1206). Optionally, data units may be combined into larger data units, e.g. nibbles may be combined into bytes (step 1208). As shown in this figure, the decoding process of an encoded block is a short and efficient algorithm for rapidly expanding an encoded data block, in particular a data key in a plurality of data blocks that forms the original data file.

In the flow diagram shown in FIG. 12B, the coding scheme for decoding an encoded data block may start with receiving an encoded data block, the encoded data block comprising a dictionary index associated with first permutation index, a first ordered data block and a second permutation index (step 1212). Then, the first permutation index may be retrieved from a dictionary using the dictionary index (step 1214). A first data block may be determined based on the first ordered data block and the second permutation index (step 1216). An original data block may be determined based on a second ordered data block and the first permutation index, wherein the first data block is used as the second ordered data block (step 1208). As shown in this figure, also in this embodiment, the decoding process of an encoded block is a short and efficient algorithm for rapidly expanding an encoded data block, in particular a data key in a plurality of data blocks that forms the original data file.

When executing the above described encoding algorithm an original file may shrink by an average of 19% for each iteration. The first iteration mostly reduces the original more than 19% in size depending on the redundancy in the original, while the dictionary grows if more data is processed. Nevertheless, the growth of the dictionary will slow down and reach an asymptotic maximum when encoding more and more data files. For example, a text file may be encoded starting with an empty dictionary.

Encoding file: C:\Book1.bd

File #: 1

Size: 544606

Iterations: 41

Encoding time: 4.69 sec. 0.08 min.

Table factor: 100.00%

Table index: 0.06%

Table extent: 9447

Total time: 4.72 sec. 0.08 min.

Encoder in: 2423462

Encoder out: 499107

Factor: 4.86

Matches: 0

Thus, the original file has a size of 544606 bytes and after 41 iterations the dictionary has a size of 499107 bytes and the data key has 245 bytes. During the iterations the encoder had to process 2423462 bytes, about four times the size of the original file but the dictionary and the associated data key file (of 245 bytes) are smaller than the original file.

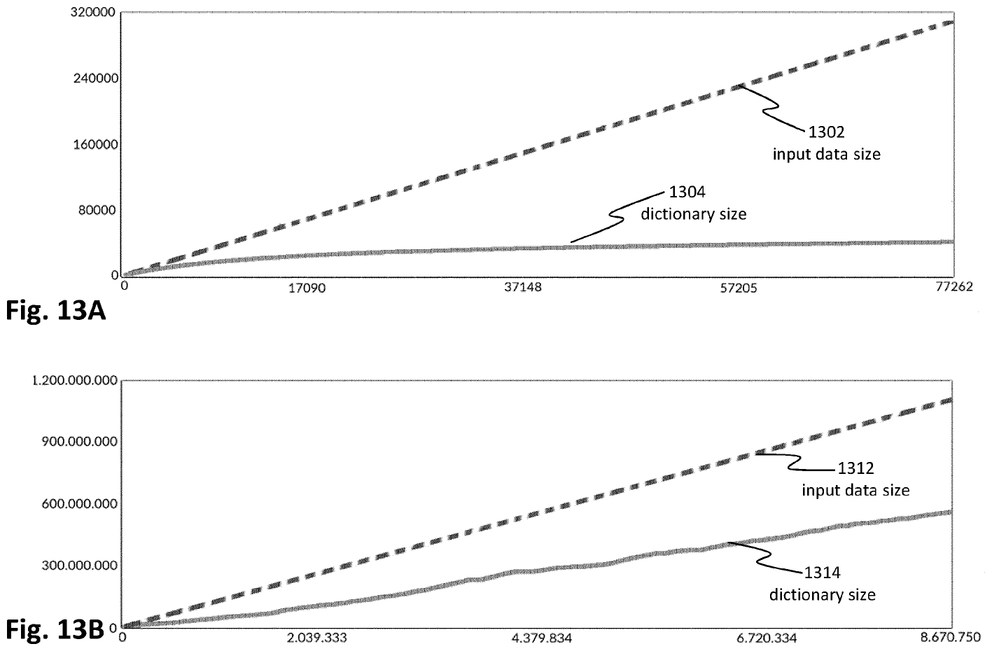

FIGS. 13A and 13B depict graphs displaying the relation between original data size and dictionary size. In particular, FIG. 13A depicts a graph showing the growth of the dictionary size slowing down as more data is processed. The graph shows the progress of encoding a fully random binary file. The horizontal axis represents the number of processed data blocks, while the vertical axis represents the size in bytes. The input data size is represented with a dashed line 1302. As in this example, a block size of 8 bytes was used, the input data size is a straight line with slope 8. The dictionary size is represented with a solid line 1304. Although the dictionary size initially grows at almost the same rate as the input data size, the curve quickly flattens and asymptotically growth towards the maximum dictionary size of, in this example, 8!=40320 entries. As each entry may be encoded with two bytes, the maximum dictionary size is 80640 bytes.

In other embodiments, a different, e.g. larger, block size may be used. In that case, it may require processing more data before the flattening of the dictionary size curve becomes clearly visible, but the general behaviour is still the same. The block size not only affects the rate of growth of the dictionary, but also the ratio between the permutation index and the permutation dictionary index, the ratio between block size and data key size (comprising a permutation dictionary index and frequency data), encoding speed and decoding speed, et cetera. Thus, a block size may be selected based on the requirements regarding one or more of the aforementioned aspects, a block size in the range 32-256.

The shape of the dictionary growth curve 1304 also depends on the redundancy in the processed data. For this example, a random file with very low redundancy was used, resulting in a smooth curve and a relatively slow flattening. Data with a higher redundancy may lead to a flatter and more irregular curve, as can be seen from curve 1314 in FIG. 13B.

FIG. 13B depicts a graph showing the growth of the dictionary size and the amount of input data for a typical use case. In this example, 6689 random Microsoft Word files were encoded. The horizontal axis represents the number of processed data blocks, while the vertical axis represents the size in bytes. The input data size is represented with a dashed line 1312. The depicted input data comprises both the data from the files and additional data from iterations. In this example, the data was iteratively processed with a block size of 128 bytes, divided into 256 nibbles as explained with reference to FIG. 3. Thus, the input data size is a straight line with slope 128. The dictionary size is represented with a solid line 1314. In this example, the size of the data keys is negligible compared to the dictionary size, and a curve representing total encoded data size (i.e., dictionary plus keys) would be indistinguishable from the curve representing the dictionary size. In this example, the growth of the dictionary size is more irregular than in FIG. 13A, with parts that are almost flat and parts that are more sloped. Flat parts indicate a redundancy, where permutation indices that are already stored in the dictionary are re-used to encode a new input file.

The exact numbers regarding input data, iteration data, and output data are as follows:

input data (files): 993,994,600 bytes

additional data (iterations): 110,582,040 bytes

processed data (files+iterations): 1,104,576,640 bytes

dictionary growth: 559,942,155 bytes

amount of keys (size): 885,441 bytes

total output size: 560,797,596 bytes

compression ratio: 56.41%

The total compression ratio is total output size, i.e. dictionary growth plus amount of keys, divided by the input data. For comparison, compressing the same input data using WinZip leads to an output file of 574,889,490 bytes, or a compression ratio of 57.83%. They keys make up only 0.16% of the output data.

It may be noted that the current example is a worst-case scenario for the described algorithm, as the example started with an empty dictionary. Thus, every permutation index is initially a new permutation index and must be added to the dictionary. In the best-case scenario, all permutations would already be in the dictionary (corresponding to the right-hand part of the graph in FIG. 13A). In that case, the added bytes to the dictionary would be zero, and hence only the keys would be generated. In that case, the compression ratio would be 885,441/993,994,600=0.089%. Realistic cases would generally fall between these two extremes.

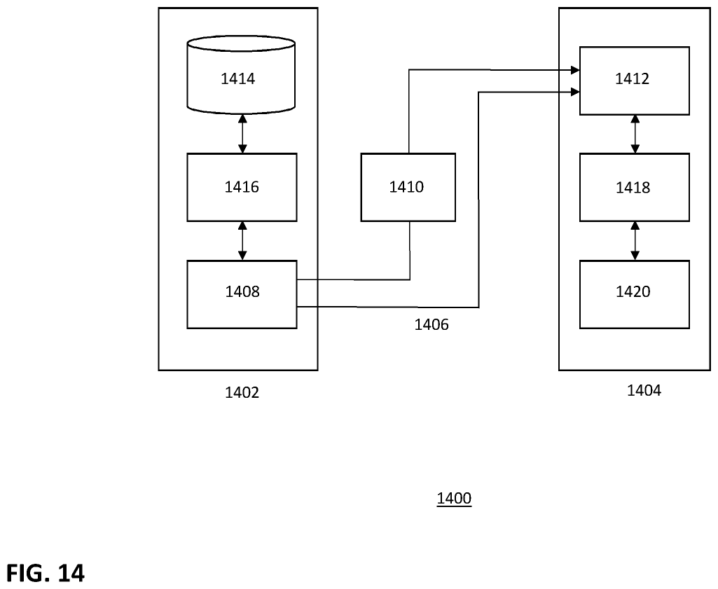

FIG. 14 depicts a schematic of encoding and decoding system 1400 that may use the encoding and decoding schemes as described in this application. As shown in FIG. 14, system 1400 may include a first data processing device 1402, configured to generate encoded data, in particular a data key, which may be decoded by a second data processing device 1404, e.g. a video playout device. First and second data processing devices may include any of a wide range of devices, including desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, or the like. In some cases, the data processing devices may be equipped for wireless communication.

The second data processing device may receive the encoded data to be decoded through a transmission channel 1406 or any type of medium or device capable of moving the encoded data from the first video processing device to the second video processing device. In one example, the transmission channel may include a communication medium to enable the first video processing device to transmit encoded data directly to the second video processing device in real-time. The encoded data may be transmitted based on a communication standard, such as a wireless communication protocol, to the second video processing device. The communication medium may comprise any wireless or wired communication medium, such as a radio frequency (RF) spectrum or one or more physical transmission lines. The communication medium may form part of a packet-based network, such as a local area network, a wide-area network, or a global network such as the Internet. The communication medium may include routers, switches, base stations, servers or any other equipment that may be useful to facilitate communication between first and second video processing devices.

Alternatively, encoded data may be sent via an I/O interface 1408 of the first data processing device to a storage device 1410. Encoded data may be accessed by input an I/O interface 1412 of the second video processing device. Storage device 1410 may include any of a variety of distributed or locally accessed data storage media such as a hard drive, Blu-ray discs, DVDs, CD-ROMs, flash memory, volatile or non-volatile memory, or any other suitable digital storage media for storing encoded video data.

In a further example, the storage device may correspond to a file server or another intermediate storage device that may hold the encoded data generated by the first video processing device. The second data processing device may access stored data from storage device via streaming or downloading. The file server may be any type of server capable of storing encoded video data and transmitting that encoded video data to the second video processing device. Example file servers include a web server (e.g., for a website), an FTP server, network attached storage (NAS) devices, or a local disk drive. The second video processing device may access the encoded video data through any standard data connection, including an Internet connection. This may include a wireless channel (e.g., a Wi-Fi connection), a wired connection (e.g., DSL, cable modem, etc.), or a combination of both that is suitable for accessing encoded video data stored on a file server. The transmission of encoded video data from storage device may be a streaming transmission, a download transmission, or a combination of both.

The techniques of this disclosure are not necessarily limited to wireless applications or settings. The techniques may be applied to coding of multimedia data, e.g. video and/or audio, in support of any of a variety of multimedia applications, such as over-the-air television broadcasts, cable television transmissions, satellite television transmissions, streaming video transmissions, e.g., via the Internet, encoding of digital video for storage on a data storage medium, decoding of digital video stored on a data storage medium, or other applications. In some examples, system 1400 may be configured to support one-way or two-way data transmission to support applications such as data streaming, video playback, video broadcasting, and/or video telephony.

In the example of FIG. 14, the first data processing device may further include a data source 1414 and an encoder 1416. In some cases, I/O interface 1408 may include a modulator/demodulator (modem) and/or a transmitter. The data source may include any type of source such as a video capture device, e.g., a video camera, a video archive containing previously captured video, a video feed interface to receive video from a video content provider, and/or a computer graphics system for generating computer graphics data as the source video, a database, a backup system and/or a combination of such sources. However, the techniques described in this disclosure may be applicable to data coding in general, and may be applied to wireless and/or wired applications.

The data may be encoded by encoder 1416. The encoded data may be transmitted directly to the second data processing device via I/O interface 1408. The encoded data may also (or alternatively) be stored onto storage device 1410 for later access by the second data processing device or other devices, for decoding and/or playback.

The second data processing device may further comprise a decoder 1418, and a display device 1420. In some cases, I/O interface 1412 may include a receiver and/or a modem. I/O interface 1412 of the second data processing device may receive the encoded data. The encoded data communicated over the communication channel, or provided on storage device 1410, may include a variety of syntax elements generated by the encoder 1416 for use by a decoder, such as decoder 1418, in decoding the video data. Such syntax elements may be included with the encoded video data transmitted on a communication medium, stored on a storage medium, or stored a file server.

Display device 1420 may be integrated with, or external to, the second video processing device. In some examples, second video processing device may include an integrated display device and also be configured to interface with an external display device. In other examples, second video processing device may be a display device. In general, display device displays the decoded video data to a user, and may comprise any of a variety of display devices such as a liquid crystal display (LCD), a plasma display, an organic light emitting diode (OLED) display, or another type of display device.

Although not shown in FIG. 14, in some aspects, encoder 1416 and decoder 1418 may each be integrated with other encoder and decoder systems, such as state of the art video and/or audio coding systems, and may include appropriate MUX-DEMUX units, or other hardware and software, to handle encoding of both audio and video in a common data stream or separate data streams.

Encoder 1416 and decoder 1418 each may be implemented as any of a variety of suitable encoder circuitry, such as one or more microprocessors, digital signal processors (DSPs), application specific integrated circuits (ASICs), field programmable gate arrays (FPGAs), discrete logic, software, hardware, firmware or any combinations thereof. When the techniques are implemented partially in software, a device may store instructions for the software in a suitable, non-transitory computer-readable medium and execute the instructions in hardware using one or more processors to perform the techniques of this disclosure. Each of encoder 1416 and decoder 1418 may be included in one or more encoders or decoders, either of which may be integrated as part of a combined encoder/decoder (codec) in a respective device.

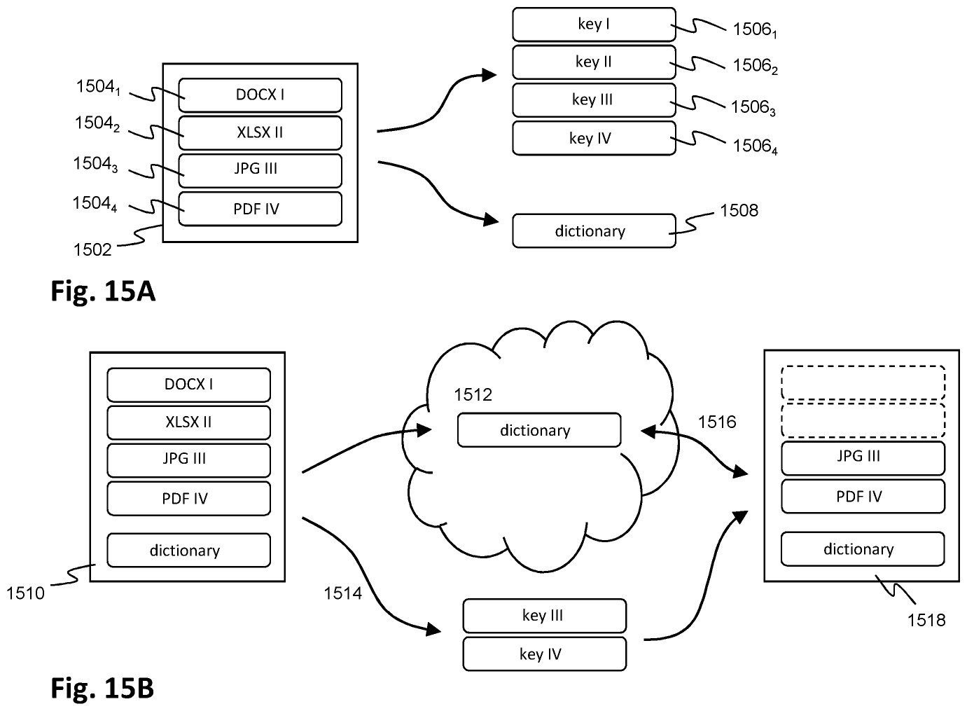

FIGS. 15A and 15B depict an exemplary application of the embodiments in this application. As shown in FIG. 15A, a data processing device 1502, e.g. a server or a computer, including a data storage comprising a large number of different files of different formats 1504₁₋₄. The data processing device may comprise an encoder apparatus as described with reference to the embodiments of this application. The encoder may encode the data file into data keys 1506₁₋₄, one for each file and a dictionary 1508.

FIG. 15B depicts a possible data distribution system including a first data processing device comprising an encoder apparatus for encoding the data into data keys and a dictionary and a second data processing device comprising a decoder apparatus. The first data processing device may upload the dictionary to a cloud storage 1512, which can be accessed by a second data processing device 1518, e.g. a computer or a mobile device. The second data processing device may download 1516 the dictionary into a memory that can be accessed by a decoder. Further, the first data processing device may be provided with one or more data keys 1514 via another communication channel, which can be used by the decoder apparatus to recover the original data files associated with the data keys.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a codec hardware unit or provided by a collection of interoperative hardware units, including one or more processors as described above, in conjunction with suitable software and/or firmware.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method of encoding data by an encoding apparatus, the method comprising:
receiving a data file or a data stream and dividing the data file or the data stream into one or more input data blocks, each input data block having a predetermined size N and comprising a sequence of data units;
iteratively encoding the data file or the data stream into a data key based on a first permutation function and a first dictionary of permutation indices, wherein iteratively encoding the data file or the data stream comprises one or more encoding iterations, each encoding iteration including:
determining a first permutation index, the determining including providing at least a first input data block to an input of the first permutation function, the first permutation index defining a permutation to generate the first input data block from a first ordered data block, the first ordered data block being obtainable by ordering the first input data block;
determining a first permutation dictionary index representing a location in the first dictionary in which the first permutation index is stored;
generating a frequency data block defining a number of occurrences for each potential data value in the first input data block;
processing the frequency data block; and
determining an encoded data block, the encoded data block comprising the first permutation dictionary index and the processed frequency data block; and
outputting the data key comprising the one or more encoded data blocks.

2. The method according to claim 1, wherein processing the frequency data block includes:
generating a second ordered data block based on the frequency data block;
determining a second permutation index defining a permutation to generate the frequency data block from the second ordered data block, the generating including providing at least the frequency data block to an input of the first permutation function; and
determining the processed frequency data block, the processed frequency data block comprising (i) a representation of the second ordered data block and (ii) the second permutation index or a second permutation dictionary index.

3. The method according to claim 1, wherein determining the first permutation index further comprises:
generating the first ordered data block based on the first input data block and providing the first ordered data block to the input of the first permutation function.

4. The method according to claim 1, further comprising:
before generating the frequency data block, converting the data units in the first input data block into ascii code; and/or
before generating the frequency data block, dividing the data units in the first input data block into smaller data units.

5. The method according to claim 1, wherein determining the first permutation dictionary index includes:
determining if the first permutation index is already stored in the first dictionary;
if the first permutation index is not stored in the first dictionary, storing the first permutation index in the first dictionary and receiving the first permutation dictionary index associated with the first permutation index;
if the first permutation index is stored in the first dictionary, receiving the first permutation dictionary index associated with the first permutation index.

6. The method according to claim 1, wherein iteratively encoding the data file or the data stream comprises generating iteration information, the iteration information providing information about a number of encoding iterations needed for encoding the data file or the data stream.

7. The method according to claim 1, wherein iteratively encoding the data file or the data stream into the data key is stopped if the size of the data key is equal to or smaller than a predetermined size.

8. (canceled)

9. A method of decoding a data key by a decoding apparatus, the data key being encoded by an encoder apparatus based on a first dictionary of permutation indices and a first permutation function, the method comprising:
receiving the data key, the data key comprising one or more encoded data blocks, an encoded data block comprising a first permutation dictionary index and a processed first frequency data block;
iteratively decoding the data key into a decoded data file or a decoded data stream based on a second permutation function and a second dictionary of permutation indices, the second dictionary comprising at least the permutation indices contained in the first dictionary associated with the data key, wherein iteratively decoding the data key comprises one or more decoding iterations, each decoding iteration comprising:
retrieving an encoded data block from the data key, the encoded data block comprising a first permutation dictionary index associated with a first permutation index and a processed first frequency data block;
retrieving the first permutation index from the second dictionary using the first permutation dictionary index;
generating a first frequency data block based on the processed first frequency data block; and
determining an original data block based on the first frequency data block and the first permutation index, the determining including providing the first frequency data block or a first ordered data block based on the first frequency data block, and the first permutation index to an input of the second permutation function; and
combining the one or more original data blocks into the decoded data file or the decoded data stream.

10. The method according to claim 9, wherein the processed first frequency data block comprises a second ordered data block and a second permutation index or a second permutation dictionary index, and wherein decoding the data key further comprises:
if the processed first frequency data block comprises the second permutation dictionary index, but not the second permutation index, then retrieving the second permutation index from the second dictionary using the second permutation dictionary index;
determining a second data block based on the second ordered data block and the second permutation index, the determining including providing the second ordered data block and the second permutation index to the input of the second permutation function; and
generating the first frequency data block based on the second data block.

11. The method according to claim 9, wherein the first dictionary was used by an encoder apparatus to encode a data file or a data stream into the data key.

12. An encoding apparatus comprising:
a computer readable storage medium having computer readable program code embodied therewith, and a processor coupled to the computer readable storage medium, wherein responsive to executing the computer readable program code, the processor is configured to perform executable operations comprising:
receiving a data file or a data stream and dividing the data file or the data stream in one or more input data blocks, each input data block having a predetermined size N and comprising a sequence of data units;
iteratively encoding the data file or the data stream into a data key based on a first permutation function and a first dictionary of permutation indices, wherein iteratively encoding the data file or the data stream comprises one or more encoding iterations, each encoding iteration including:
determining a first permutation index the determining including providing at least a first input data block to an input of the first permutation function, the first permutation index defining a permutation to generate the first input data block from a first ordered data block, the first ordered data block being obtainable by ordering the first input data block;
determining a first permutation dictionary index representing a location in the first dictionary in which the first permutation index is stored;
generating a frequency data block defining a number of occurrences for each potential data value in the first input data block;
processing the frequency data block; and
determining an encoded data block, the encoded data block comprising the first permutation dictionary index and the processed frequency data block; and
outputting the data key comprising the one or more encoded data blocks.

13. The encoding apparatus according to claim 12, wherein processing the frequency data block includes:
generating a second ordered data block based on the frequency data block;
determining a second permutation index defining a permutation to generate the frequency data block from the second ordered data block, the generating including providing at least the frequency data block to an input of the first permutation function; and
determining the processed frequency data block, the processed frequency data block comprising (i) a representation of the second ordered data block and (ii) the second permutation index or a second permutation dictionary index.

14. The encoding apparatus according to claim 12, wherein before generating the frequency data block, the executable operations comprise:
converting the data units in the first input data block into ascii code; and/or
dividing the data units in the first input data block into smaller data units.

15. The encoding apparatus according to claim 12, wherein determining the first permutation dictionary index includes:
determining if the first permutation index is already stored in the first dictionary;
if the first permutation index is not stored in the first dictionary, storing the first permutation index in the first dictionary and receiving the dictionary index associated with the first permutation index;
if the first permutation index is stored in the first dictionary, receiving the first permutation dictionary index associated with the first permutation index.

16. The encoding apparatus according to claim 12, wherein iteratively encoding the data file or the data stream comprises generating iteration information, the iteration information providing information about a number of encoding iterations needed for encoding the data file or the data stream.

17. (canceled)

18. A decoding apparatus comprising:
a computer readable storage medium having computer readable program code embodied therewith, and a processor coupled to the computer readable storage medium, wherein responsive to executing the computer readable program code, the processor is configured to perform executable operations comprising:
receiving a data key, the data key comprising one or more encoded data blocks, an encoded data block comprising a first permutation dictionary index and a processed first frequency data block;
iteratively decoding the data key into a decoded data file based on a second permutation function and a second dictionary of permutation indices, the second dictionary comprising at least the permutation indices contained in a first dictionary associated with the data key, wherein iteratively decoding the data key comprises one or more decoding iterations, each decoding iteration comprising:
retrieving an encoded data block from the data key, the encoded data block comprising a first permutation dictionary index associated with a first permutation index and a processed first frequency data block;
retrieving the first permutation index from the second dictionary using the first permutation dictionary index;
generating a first frequency data block based on the processed first frequency data block; and
determining an original data block based on the first frequency data block and the first permutation index, the determining including providing the first frequency data block or a first ordered data block based on the first frequency data block, and the first permutation index to an input of the second permutation function; and
combining the one or more original data blocks into a decoded data file or a decoded data stream.

19. The decoding apparatus according to claim 18, wherein the processed first frequency data block comprises a second ordered data block and a second permutation index or a second permutation dictionary index, and wherein decoding the data key further comprises:
if the processed first frequency data block comprises the second permutation dictionary index, but not the second permutation index, then retrieving the second permutation index from the second dictionary using the second permutation dictionary index;
determining a second data block based on the second ordered data block and the second permutation index, the determining including providing the second ordered data block and the second permutation index to the input of the second permutation function; and
generating the first frequency data block based on the second data block.

20. The decoding apparatus according to claim 18, wherein the second dictionary comprises the same permutation indices as the permutation indices of a first dictionary that was used by an encoder apparatus to encode a data file or a data stream into the data key.

21. A non-transitory computer-readable storage medium having encoded thereon software code portions configured for, when run on a computer, executing the method steps according to claim 1.

22. A non-transitory computer-readable storage medium having encoded thereon software code portions configured for, when run on a computer, executing the method steps according to claim 9.
